(19) United States
(12) Patent Application Publication
(10) Pub. No.: US 2026/0184895 A1
(43) Pub. Date: Jul. 2, 2026

(54) PREPOLYMER, RESIN COMPOSITION INCLUDING THE SAME AND ARTICLE MADE THEREFROM

(71) Applicant: ELITE ELECTRONIC MATERIAL (KUNSHAN) CO., LTD., Kunshan City (CN)

(72) Inventors: Jinke WU, Kunshan City (CN); Yan ZHANG, Kunshan City (CN); Diya LIU, Kunshan City (CN); Xingxing YAO, Kunshan City (CN)

(73) Assignee: ELITE ELECTRONIC MATERIAL (KUNSHAN) CO., LTD., Kunshan City (CN)

(21) Appl. No.: 19/090,524

(22) Filed: Mar. 26, 2025

(30) Foreign Application Priority Data
Dec. 31, 2024 (CN) 2024120003434

(51) Int. Cl. C08K 5/5435; B32B 5/02; B32B 5/26; C08J 5/24; C08K 5/5419; C08L 79/08

(52) U.S. Cl. CPC C08K 5/5435; B32B 5/02; B32B 5/26; C08J 5/244; C08K 5/5419; C08L 79/08; B32B 2250/05; B32B 2250/20; B32B 2250/40; B32B 2255/02; B32B 2255/205; B32B 2260/023; B32B 2260/046; B32B 2262/101; B32B 2307/30; B32B 2307/308; B32B 2307/734; B32B 2307/748; B32B 2457/08; C08J 2379/08

(57) ABSTRACT

The present discloses a prepolymer, a resin composition including the same, and article made therefrom, where the prepolymer is obtained from a mixture through a prepolymerization reaction. The mixture includes: (a) a maleimide resin, (b) an epoxy-modified cyclic siloxane, (c) an active hydrogen-containing compound. The active hydrogen-containing compound includes an aminosiloxane, a diallyl bisphenol, or a combination thereof. The prepolymer and the resin composition including the same of the present disclosure may significantly improve one or more of uniformity of an X-CTE of the article, copper foil peeling strength after copper plating, dimension stability after solder floating, and heterogeneous resin flow length.

### CROSS-REFERENCE TO RELATED APPLICATIONS

This non-provisional application claims priority under 35 U.S.C. § 119(a) on patent application No. 2024120003434 filed in China on Dec. 31, 2024, the entire contents of which are hereby incorporated by reference.

### BACKGROUND

### 1. Technical Field

The present disclosure relates to a prepolymer, resin composition including the same and article made therefrom, particularly to a prepolymer and resin composition including the same which may be applied to prepregs, resin films, laminates (e.g. copper-clad laminates) and printed circuit boards (PCBs).

### 2. Related Art

Currently, electronic devices, such as mobile phones and personal computers, are continuously evolving toward high performance and miniaturization. This trend has been driving the advancements in semiconductor packaging technology and placing increasingly stringent demands on printed circuit boards used for semiconductor packaging.

Maleimide resin, which exhibits excellent heat resistance, electrical insulation, flame retardancy and dimension stability, etc., is a commonly used base resin for IC packaging substrates and substrate-like PCBs. However, it also has drawbacks such as poor solubility and easy precipitation, leading to uneven characteristics and high brittleness of the produced copper-clad laminate, which greatly limits its application development.

In order to meet the growing demand in the current substrate market, research on the modification of maleimide resin has become a new hot spot. However, the articles made from maleimide resin currently on the market still have defects such as poor uniformity of the coefficient of thermal expansion at X-axis, low copper foil peeling strength after copper plating, low dimension stability after solder floating, long heterogeneous resin flow length.

### SUMMARY

In view of the above problems in the prior arts, specifically, the current material is unable to meet the technical demands, the main purpose of the present disclosure is to provide a prepolymer, a resin composition including the prepolymer, and an article made from the resin composition. The prepolymer of the present disclosure has an extremely high glass transition temperature and is able to solve at least one of the above technical problems.

In one aspect, the present disclosure provides a prepolymer which is obtained from a mixture through a prepolymerization reaction, where the mixture includes:
(a) a maleimide resin,
(b) an epoxy-modified cyclic siloxane, and
(c) an active hydrogen-containing compound,
wherein the active hydrogen-containing compound includes an aminosiloxane, a diallyl bisphenol, or a combination thereof.

In one embodiment, with respect to 100 parts by weight of the maleimide resin, the amount of the epoxy-modified cyclic siloxane ranges from 3 to 30 parts by weight, and the amount of the active hydrogen-containing compound ranges from 5 to 45 parts by weight.

In one embodiment, with respect to 100 parts by weight of the maleimide resin, the amount of the epoxy-modified cyclic siloxane ranges from 3 to 25 parts by weight, and the amount of the active hydrogen-containing compound ranges from 5 to 40 parts by weight.

In one embodiment, the weight average molecular weight of the prepolymer ranges from 3000 to 5000.

In one embodiment, the conversion rate of the prepolymerization reaction ranges from 1 to 99%, preferably from 10 to 90%.

In one embodiment, the maleimide resin includes an oligomeric maleimide resin, a non-oligomeric maleimide resin, or a combination thereof.

In one embodiment, the maleimide resin includes 70 to 100 wt % non-oligomeric maleimide resin and 0 to 30 wt % oligomeric maleimide resin.

In one embodiment, the oligomeric maleimide resin includes a poly (phenylmethane maleimide), an indane-containing maleimide, an isopropyl group and meta-arylene-containing maleimide, a biphenyl alkylene-containing maleimide, a maleimide containing an aliphatic structure with 10 to 50 carbon atoms, or a combination thereof.

In one embodiment, the non-oligomeric maleimide resin includes a 4,4′-diphenylmethane bismaleimide, a bisphenol A diphenyl ether bismaleimide, a 3,3′-dimethyl-5,5′-diethyl-4,4′-diphenylmethane bismaleimide, a 3,3′-dimethyl-5,5′-dipropyl-4,4′-diphenylmethane bismaleimide, an meta-phenylene bismaleimide, a 4-methyl-1,3-phenylene bismaleimide, a 1,6-bismaleimide-(2,2,4-trimethyl) hexane, an N-2,3-xylylmaleimide, an N-2,6-xylylmaleimide, an N-phenylmaleimide, a vinyl benzyl maleimide (VBM), or a combination thereof.

In one embodiment, the epoxy-modified cyclic siloxane includes a structure represented by Formula (1):

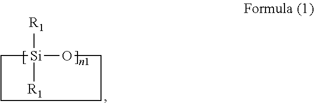

In Formula (1), n1 is an integer ranging from 3 to 6, multiple R₁ groups may be the same or different, at least one of the multiple R₁ groups is a group containing an epoxy group, and each R₁ group is independently C1 to C3 alkyl group,

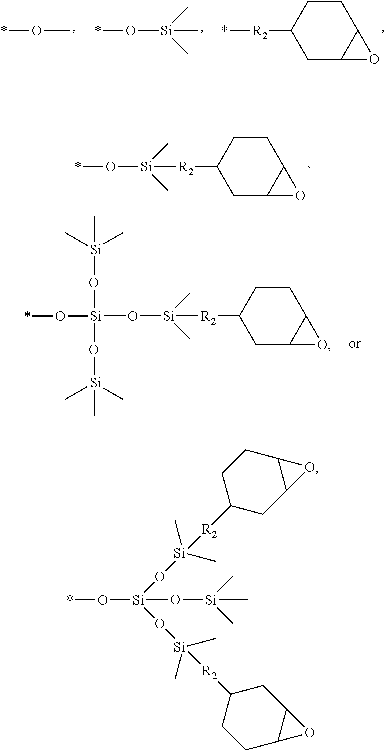

wherein, each R₂ group is independently C1 to C3 alkyl group.

In one embodiment, the epoxy-modified cyclic siloxane includes any one of a structure represented by Formula (1-1) to Formula (1-3), or a combination thereof:

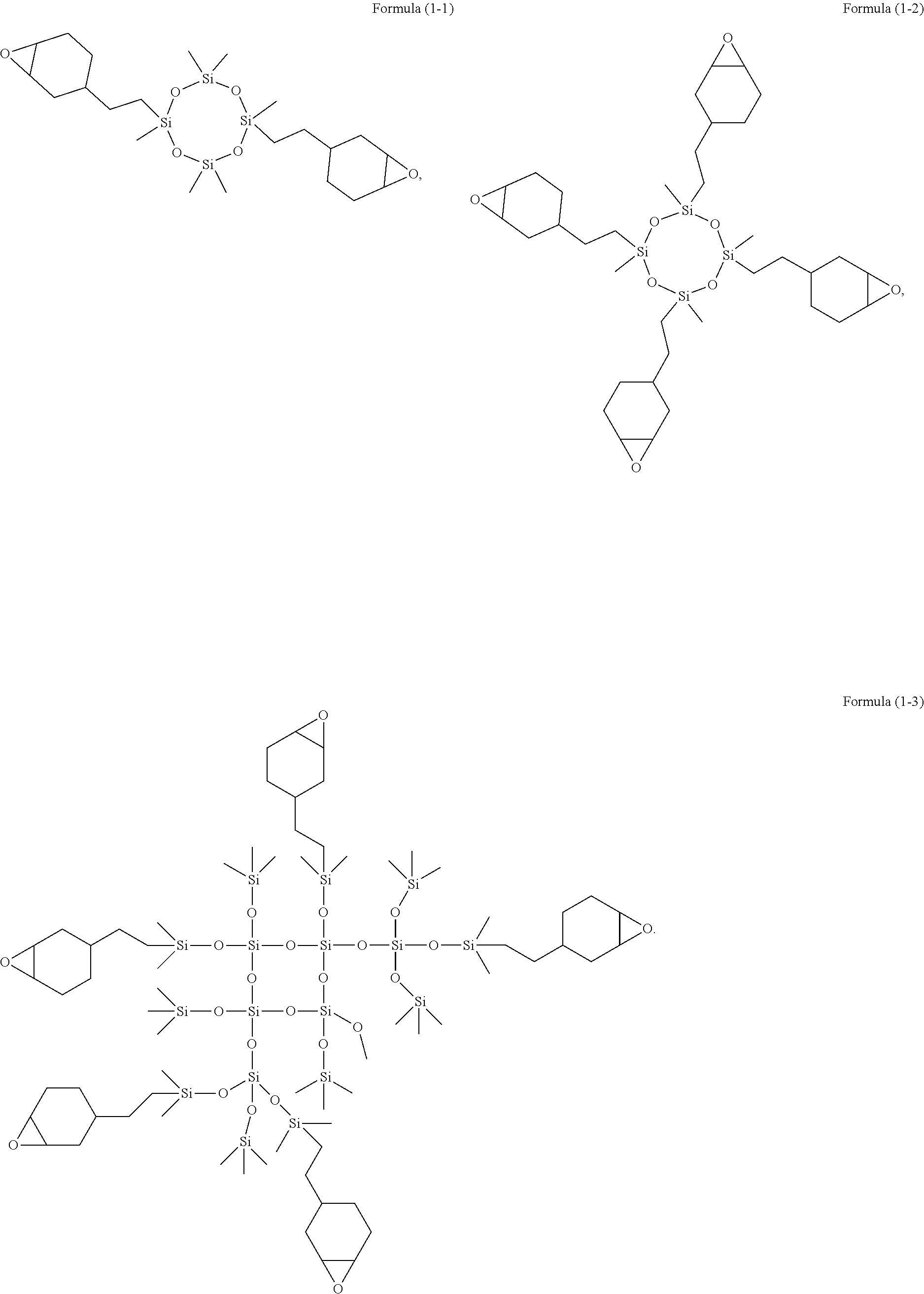 [SMILES: C[Si]1(C)O[Si](C)(CCC2CCC3OC3C2)O[Si](C)(C)O[Si](C)(CCC2CCC3OC3C2)O1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O1 ; CO[Si]1(O[Si](C)(C)C)O[Si](O[Si](C)(C)C)(O[Si](O[Si](C)(C)C)(O[Si](C)(C)CCC2CCC3OC3C2)O[Si](C)(C)CCC2CCC3OC3C2)O[Si](O[Si](C)(C)C)(O[Si](C)(C)CCC2CCC3OC3C2)O[Si](O[Si](C)(C)CCC2CCC3OC3C2)(O[Si](O[Si](C)(C)C)(O[Si](C)(C)C)O[Si](C)(C)CCC2CCC3OC3C2)O1]

In one embodiment, the aminosiloxane includes a structure represented by Formula (2):

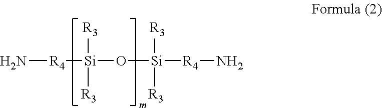

In Formula (2), multiple R₃ groups may be the same or different, each R₃ group is independently alkyl group, phenyl group, or alkoxy group, multiple R₄ groups may be the same or different, each R₄ group is independently alkylene, alkenylene, alkynylene, arylene, or —O—, and m is an integer ranging from 1 to 100.

In one embodiment, the diallyl bisphenol includes a diallyl bisphenol A, a diallyl bisphenol F, a diallyl biphenol, or a combination thereof.

In other aspect, the present disclosure provides a resin composition, where the resin composition includes the aforesaid prepolymer.

In one embodiment, the resin composition further includes a crosslinking agent, an organic silicone resin, an epoxy resin, a maleimide resin, or a combination thereof.

In one embodiment, the resin composition further includes a polyphenylene ether resin, a polyolefin resin, a benzoxazine resin, a polyester resin, a phenol resin, an amine curing agent, a polyamide, a polyimide, a cyanate ester resin, a maleimide triazine resin, or a combination thereof.

In one embodiment, the resin composition further includes a curing accelerator, a polymerization inhibitor, a flame retardant, an inorganic filler, a surfactant, a coloring agent, a toughening agent, a solvent, or a combination thereof.

In still other aspect, the present disclosure provides an article, where the article is made by the aforesaid resin composition, and the article includes a prepreg, a resin film, a laminate, or a printed circuit board.

In one embodiment, the article has at least one of the following properties:
an X-CTE at board center of less than or equal to 3.8 ppm/° C. as measured and calculated by reference to IPC-TM-650 2.4.24.5;
an X-CTE at board edge of less than or equal to 4.0 ppm/° C. as measured and calculated by reference to IPC-TM-650 2.4.24.5;
a difference between the X-CTE at board center and the X-CTE at board edge of less than or equal to 0.3 ppm/° C. as measured and calculated by reference to IPC-TM-650 2.4.24.5;
a copper foil peeling strength after copper plating of greater than or equal to 5.0 lb/in as measured by reference to IPC-TM-650 2.4.8;
a dimension change Cpk of a substrate after solder floating of greater than or equal to 1.35 as measured and calculated by reference to IPC-TM-650 2.4.39;
a glass transition temperature of greater than or equal to 330° C. as measured by reference to IPC-TM-650 2.4.24.4.

### DETAILED DESCRIPTION

In order to enable those skilled in the art to understand the technical contents of the present disclosure clearly and correctly, the following mentioned terms and signs in the specification will generally be illustrated and defined. Unless otherwise specified, all of the terms and signs (including scientific terms, technical terms, and common signs, where common signs include common mathematical, physical, and chemical signs, etc.) used herein have the common meaning as understood by those skilled in the art and should not be interpreted in an idealized or unduly formal manner.

As used herein, “any one of . . . , or a combination thereof” should be interpreted as “using any one of the listed elements alone,” “using any two of the listed elements in combination,” or “using any three or more of the listed elements in combination.”

As used herein, a number range expressed by “equal to,” “=,” “greater than or equal to,” “≥,” “less than or equal to,” “≤,” “to,” “˜,” “−,” “or more,” or “or less” should be interpreted as including the endpoints values. Additionally, the interpretation should cover all possible subranges and individual values within the range (the numeric type includes, but not limited to, integers, decimals, and fractions). For instance, a number range expressed as “equal to 3.0,” “=3.0,” “greater than or equal to 3.0,” “≥3.0,” “less than or equal to 3.0,” “≤3.0,” “3.0 or more,” or “3.0 or less” all include the endpoint value “3.0;” a number range expressed as “3.0 to 6.0,” “3.0˜6.0,” “3.0-6.0” all include the endpoint values “3.0” and “6.0”, and should be understood to include, but not be limited to, subranges such as 3.0-5.0, 4.0-6.0, and 5.0-6.0, as well as individual values such as 3.0, 4.0, 5.0, 5.5, and 6.0.

As used herein, a number range expressed as “greater than,” “>,” “less than,” or “<” should be interpreted as excluding the endpoint values. For instance, a number range expressed as “greater than 3.0,” “>3.0,” “less than 3.0,” or “<3.0” all exclude the endpoint value “3.0.”

As used herein, the numerical values have a degree of accuracy, which is determined by using the round off method.

As used herein, “unsaturated carbon-carbon double bond-containing” means “a group containing unsaturated C═C double bond group,” such as, but not limited to, vinyl group, vinylbenzyl group, (meth)acryloyl group, allyl group. Among them, “vinyl group” should be interpreted as including vinyl group and vinylidene group, and “(meth)acryloyl group” should be interpreted as including acryloyl group and methylacryloyl group.

As used herein, functional groups, such as alkyl group and alkenyl group, should be interpreted as including various isomers thereof. For instance, “alkyl group” refers to a group derived from an aliphatic hydrocarbon and includes linear, branched, or cyclic groups. For a further example, propyl group should be interpreted as including n-propyl group and isopropyl group.

As used herein, “monomer” or “compound” should be interpreted as including various isomers thereof, such as, but not limited to, constitutional isomer and stereoisomer.

As used herein, “part(s) by weight” should be interpreted as relative part(s) by weight, which may be any weight unit, such as but not limited to kilogram, gram, pound or the like.

As used herein, wt % refers to weight (or mass) percentage.

As used herein, mil is a unit of thickness, where 1 mil is approximately equal to 25.4 micrometers; ounce is also a unit of thickness, where 1 ounce is approximately equal to 35 micrometers.

As used herein, a polymer includes a copolymer and a homopolymer. If not specified, the degree of polymerization (conversion rate) of the polymer is not limited. For instance, it can be a fully polymerized polymer (with a conversion rate of 100%) or a partially polymerized polymer (with a conversion rate between, for example, but not limited to, 1% and 99%), and it may also be referred to as a “prepolymer” as used herein). The molecular weight of the polymer is not limited. For instance, a polymer formed by 2 to 20 repeating units is referred to as an oligomer (or low polymer). Generally, an oligomer is a polymer formed by 2 to 5 repeating units.

As used herein, the molecular weight of the prepolymer refers to the molecular weight of the product formed when the monomer undergoes partial polymerization and reaches an intermediate molecular weight state. The molecular weight of the product is greater than the molecular weight of the monomer before the reaction but less than the molecular weight of the final polymer product obtained after complete reaction. Also, the prepolymer contains reactive functional group which may further undergo polymerization, leading to a fully crosslinked or cured high molecular weight product.

As used herein, a resin composition, which is obtained from the addition of prepolymers partial polymerized from different compounds, is different from a resin composition, which is obtained by separate addition of the compounds without prior partial polymerization. For instance, a resin composition 1, which is obtained from the addition of prepolymers of compound A, compound B, and compound C, is different from a resin composition 2, which is obtained by separate addition of compound A, compound B, and compound C without prior partial polymerization, and their articles and properties thereof are also different.

As used herein, an oligomeric maleimide resin refers to a maleimide resin having repeating units and an average degree of polymerization ranging from 0.5 to 20. Generally, it is a mixture of maleimides with two or more different degrees of polymerization. A non-oligomeric maleimide resin refers to a maleimide resin that does not contain repeating units and has a clear molecular structure.

Examples and embodiments are described in detail below. These embodiments are merely exemplary of preferred specific examples and are not intended to limit the scope of the present disclosure.

As mentioned above, the present disclosure discloses a prepolymer, where the prepolymer is obtained from a mixture through a prepolymerization reaction. The mixture includes:
(a) a maleimide resin,
(b) an epoxy-modified cyclic siloxane, and
(c) an active hydrogen-containing compound,
The active hydrogen-containing compound includes an aminosiloxane, a diallyl bisphenol, or a combination thereof.

In one embodiment, the weight average molecular weight of the prepolymer of the present disclosure ranges from 3000 to 5000.

The amount of the epoxy-modified cyclic siloxane and the amount of the active hydrogen-containing compound are calculated based on a total of 100 parts by weight of the maleimide resin. For instance, without limitation, with respect to 100 parts by weight of the maleimide resin, the amount of the epoxy-modified cyclic siloxane ranges from 3 to 30 parts by weight, preferably from 3 to 25 parts by weight. Examples include, but are not limited to, 3 parts by weight, 10 parts by weight, 15 parts by weight, 20 parts by weight, 25 parts by weight, 28 parts by weight, 30 parts by weight. With respect to 100 parts by weight of the maleimide resin, the amount of the active hydrogen-containing compound ranges from 5 to 45 parts by weight, preferably from 5 to 40 parts by weight. Examples include, but are not limited to, 5 parts by weight, 10 parts by weight, 15 parts by weight, 20 parts by weight, 25 parts by weight, 30 parts by weight, 35 parts by weight, 40 parts by weight, 42 parts by weight, 45 parts by weight.

The prepolymerization reaction is a process in which a prepolymer is obtained through the partial polymerization of one or more monomers, where the conversion rate of the monomer is between 0% and 100% (excluding 0% and 100%). A small amount of unreacted monomers that did not undergo prepolymerization can enhance the compatibility of the prepolymer resin in the resin composition and increase the degree of crosslinking. Specifically, a monomer conversion rate of 0% indicates that the monomer has not reacted at all, making the formation of a prepolymer impossible. Similarly, a monomer conversion rate of 100% indicates that the monomer has fully reacted, also making the formation of a prepolymer impossible. Preferably, the momoner conversion rate of the prepolymer of the present disclosure is between 1% and 99%; more preferably, the monomer conversion rate is, for example but not limited to, between 10% and 90%. The method for determining the monomer conversion rate of the present disclosure is not particularly limited and can be tested by using various methods known in this field, such as, but not limited to, using gas chromatography to analyze the monomer conversion rate.

In one embodiment, the maleimide resin includes an oligomeric maleimide resin, a non-oligomeric maleimide resin, or a combination thereof.

In one embodiment, the maleimide resin includes 70 to 100 wt % non-oligomeric maleimide resin and 0 to 30 wt % oligomeric maleimide resin.

In one embodiment, the oligomeric maleimide resin includes a poly (phenylmethane maleimide), an indane-containing maleimide, an isopropyl group and meta-arylene-containing maleimide, a biphenyl alkylene-containing maleimide, a maleimide containing an aliphatic structure with 10 to 50 carbon atoms, or a combination thereof.

The oligomeric maleimide resin includes maleimide resin products such as BMI-2000 and BMI-2300 available from Daiwakasei Industry, maleimide resin products such as MIR-3000 or MIR-5000 available from Nippon Kayaku, indane-containing maleimide resin available from DIC Corporation. The maleimide containing an aliphatic structure with 10 to 50 carbon atoms, also known as imide-extended maleimide resin, may include various imide-extended maleimide resins disclosed in the TW Patent Application Publication No. 200508284A, all of which are incorporated herein by reference in their entirety. The maleimide containing an aliphatic structure with 10 to 50 carbon atoms suitable for the present disclosure may include, but not limited to, products such as BMI-1400, BMI-1500, BMI-1700, BMI-2500, BMI-3000, BMI-5000, and BMI-6000 available from Designer Molecules Inc.

In one embodiment, the non-oligomeric maleimide resin includes a 4,4′-diphenylmethane bismaleimide, a bisphenol A diphenyl ether bismaleimide, a 3,3′-dimethyl-5,5′-diethyl-4,4′-diphenylmethane bismaleimide, a 3,3′-dimethyl-5,5′-dipropyl-4,4′-diphenylmethane bismaleimide, an meta-phenylene bismaleimide, a 4-methyl-1,3-phenylene bismaleimide, a 1,6-bismaleimide-(2,2,4-trimethyl) hexane, an N-2,3-xylylmaleimide, an N-2,6-xylylmaleimide, an N-phenylmaleimide, a vinyl benzyl maleimide (VBM), or a combination thereof.

The non-oligomeric maleimide resin includes, but not limited to, products such as BMI-1000, BMI-1000H, BMI-1100, BMI-1100H, BMI-3000, BMI-3000H, BMI-4000, BMI-5000, BMI-5100, BMI-TMH, BMI-7000, and BMI-7000H available from Daiwakasei Industry Co., Ltd., or products such as BMI-70, BMI-80 available from K.I Chemical Industry Co., Ltd.

In one embodiment, the epoxy-modified cyclic siloxane includes a structure represented by Formula (1):

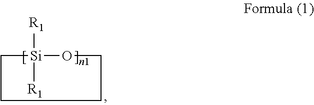

In Formula (1), n1 is an integer ranging from 3 to 6, multiple R₁ groups may be the same or different, at least one of the multiple R₁ groups is a group containing an epoxy group, and each R₁ group is independently C1 to C3 alkyl group,

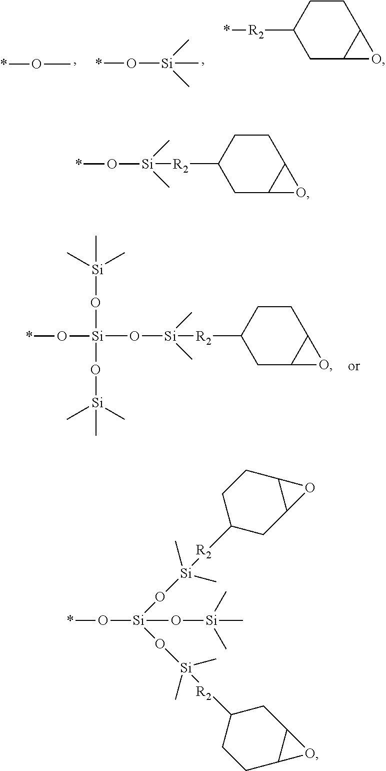

wherein, each R₂ group is independently C1 to C3 alkyl group.

In one embodiment, the epoxy-modified cyclic siloxane includes any one of a structure represented by Formula (1-1) to Formula (1-3), or a combination thereof:

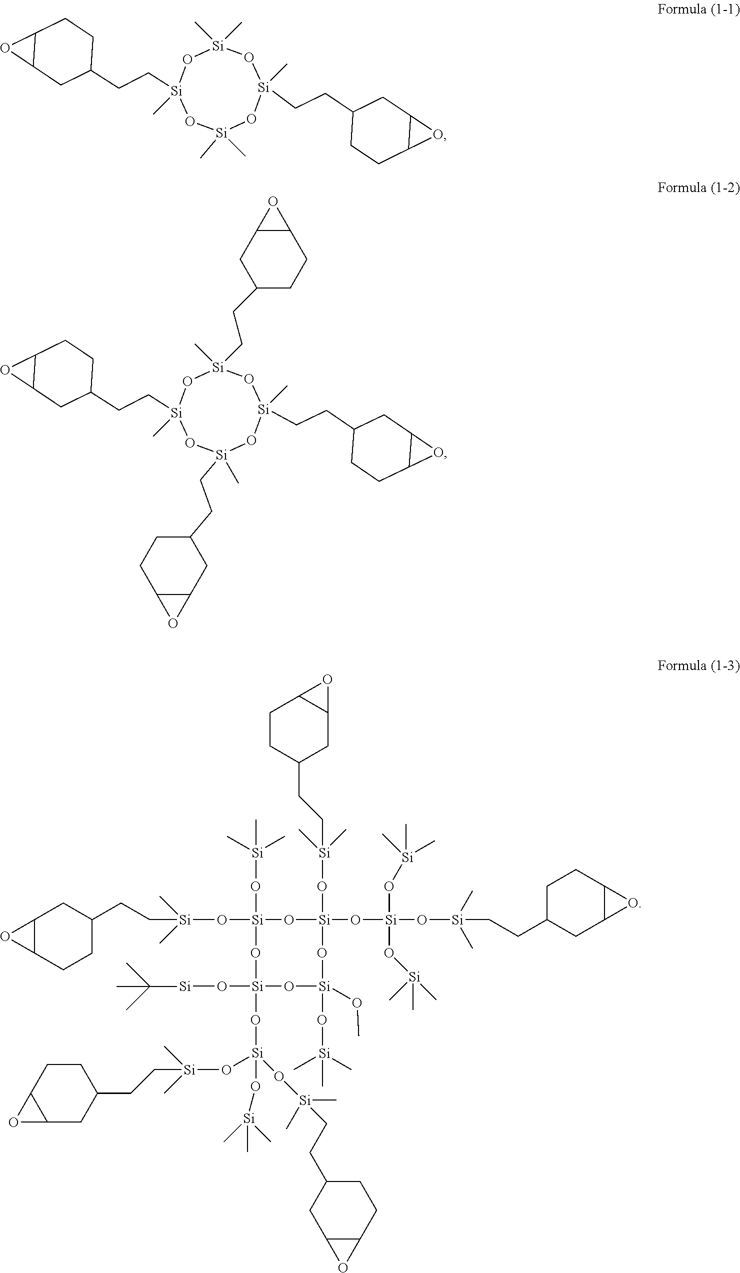

In one embodiment, the aminosiloxane includes a structure represented by Formula (2):

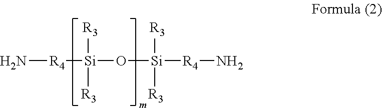

In Formula (2), multiple R₃ groups may be the same or different, each R₃ group is independently alkyl group, phenyl group, or alkoxy group, multiple R₄ groups may be the same or different, each R₄ group is independently alkylene, alkenylene, alkynylene, arylene, or —O—, and m is an integer ranging from 1 to 100.

The aminosiloxane suitable for the present disclosure includes, but not limited to, products such as PAM-E, KF-8010, X-22-161A, X-22-161B, KF-8012, KF-8008, X-22-9409, and X-22-1660B-3 available from Shin-Etsu Chemical Co., Ltd., products such as BY-16-853U, BY-16-853, BY-16-853B available from Toray-Dow corning Co., Ltd., or a combination thereof.

In one embodiment, the diallyl bisphenol includes a diallyl bisphenol A, a diallyl bisphenol F, a diallyl biphenol, or a combination thereof.

In another aspect, the present disclosure further provides a resin composition including the aforesaid prepolymer.

In one embodiment, the resin composition further includes a crosslinking agent, an organic silicone resin, an epoxy resin, a maleimide resin, or a combination thereof.

The crosslinking agent includes bis(vinylphenyl) ethane (BVPE), divinylbenzene (DVB), divinylnaphthalene, divinylbiphenyl, triallyl isocyanurate (TAIC), triallyl cyanurate (TAC), vinyl benzocyclobutene (VBCB), bis(vinylbenzyl) ether (BVBE), diallyl bisphenol A, diallyl bisphenol F, diallyl biphenyl, trivinylcyclochexane (TVCH), bifunctional or higher acrylate, butadiene, decadiene, octadiene, or a combination thereof. With respect to 100 parts by weight of the prepolymer of the present disclosure, the amount of the crosslinking agent ranges from 0 to 30 parts by weight.

The bifunctional or higher acrylate includes, but not limited to, bifunctional acrylate, trifunctional acrylate, or tetrafunctional or higher acrylate, available from Shin-Nakamura Chemical Industry Co., Ltd., Kyoeisha Chemical Co., Ltd., Nippon Kayaku, or Sartomer. The bifunctional acrylate includes, but not limited to, diallyl isophthalate (DAIP), dioxanediol diacrylate, tricyclodecane dimethanol diacrylate, tricyclodecane dimethanol dimethacylate, or a combination thereof.

The organic silicone resin includes, but not limited to, polyalkylsiloxane, polyarylsiloxane, polyalkarylsiloxane, modified polysiloxane or a combination thereof. The modified polysiloxane includes, but not limited to, methylacryloyl group-modified organic silicone resin, hydroxyl group-modified organic silicone resin, carboxy group-modified organic silicone resin, amino group-modified organic silicone resin (including the aforesaid aminosiloxane), epoxy group-modified organic silicone resin, or a combination thereof. With respect to 100 parts by weight of the prepolymer of the present disclosure, the amount of the organic silicone resin ranges from 0 to 20 parts by weight.

The epoxy resin may be various epoxy resins known in this fiels. In terms of improving the heat resistance of the resin composition, the epoxy resin includes, but not limited to, any one of bisphenol A epoxy resin, bisphenol F epoxy resin, bisphenol S epoxy resin, bisphenol AD epoxy resin, novolac epoxy resin, trifunctional epoxy resin, tetrafunctional epoxy resin, multifunctional novolac epoxy resin, dicyclopentadiene (DCPD) epoxy resin, phosphorus-containing epoxy resin, p-xylene epoxy resin, naphthalene epoxy resin (such as naphthol epoxy resin), benzofuran epoxy resin, isocyanate-modified epoxy resin, or a combination thereof. As used herein, the novolac epoxy resin may be phenol novolac epoxy resin, bisphenol A novolac epoxy resin, bisphenol F novolac epoxy resin, biphenyl novolac epoxy resin, phenol benzaldehyde epoxy resin, phenol aralkyl novolac epoxy resin or o-cresol novolac epoxy resin. As used herein, the phosphorus-containing epoxy resin may be DOPO (9,10-dihydro-9-oxa-10-phosphaphenanthrene-10-oxide) epoxy resin, DOPO-HQ epoxy resin, or a combination thereof. The DOPO epoxy resin may be selected from one or more of DOPO-containing phenol novolac epoxy resin, DOPO-containing o-cresol novolac epoxy resin and DOPO-containing bisphenol-A novolac epoxy resin. The DOPO-HQ epoxy resin may be selected from one or more of DOPO-HQ-containing phenol novolac epoxy resin, DOPO-HQ-containing o-cresol novolac epoxy resin and DOPO-HQ-containing bisphenol-A novolac epoxy resin, but not limited thereto. With respect to 100 parts by weight of the prepolymer of the present disclosure, the amount of the epoxy resin ranges from 0 to 20 parts by weight.

The maleimide resin suitable for the present disclosure, as described above, includes various oligomeric maleimide resins, non-oligomeric maleimide resins, or a combination thereof. With respect to 100 parts by weight of the prepolymer of the present disclosure, the amount of the maleimide resin ranges from 0 to 70 parts by weight.

In one embodiment, the resin composition further includes a polyphenylene ether resin, a polyolefin resin, a benzoxazine resin, a polyester resin, a phenol resin, an amine curing agent, a polyamide, a polyimide, a cyanate ester resin, a maleimide triazine resin, or a combination thereof.

If not specified, in the resin composition of the present disclosure, the amounts of each component are calculated based on a total of 100 parts by weight of the maleimide resin of the present disclosure. For instance, with respect to 100 parts by weight of the prepolymer of the present disclosure, the amounts of the polyphenylene ether resin, polyolefin resin, benzoxazine resin, polyester resin, phenol resin, polyamide, polyimide, cyanate ester resin, maleimide triazine resin are not particularly limited, and may be adjusted as needed. Each component may range independently from 1 part by weight to 100 parts by weight, for example but not limited to, 1 part by weight, 5 parts by weight, 10 parts by weight, 15 parts by weight, 20 parts by weight, 25 parts by weight, 50 parts by weight, or 100 parts by weight. With respect to 100 parts by weight of the prepolymer of the present disclosure, the amount of the amine curing agent is not particularly limited, and may be adjusted as needed. The amount of the amine curing agent may range from 1 part by weight to 30 parts by weight.

The polyphenylene ether resin suitable for the present disclosure is not particularly limited, may be various polyphenylene ether resins known in this field, any one or more of commercial products, homemade products or a combination thereof, such as but not limited to hydroxy group-containing polyphenylene ether resin (such as SA90, SA120, available from Sabic), unsaturated C═C double bond-containing polyphenylene ether resin, or a combination thereof. The unsaturated C═C double bond-containing polyphenylene ether resin includes any one of vinylbenzyl group-containing polyphenylene ether resin, (meth)acryloyl group-containing polyphenylene ether resin, vinyl group-containing polyphenylene ether resin, allyl group-containing polyphenylene ether resin, or a combination thereof.

The unsaturated C═C double bond-containing polyphenylene ether resin has unsaturated C═C double bonds and a backbone of phenyl ether, in which the unsaturated C═C double bonds are reactive functional groups, which may be self-polymerized after heated and may perform free radical polymerization with other components containing an unsaturated bond in the resin composition and finally result in crosslinking and curing. Preferably, the unsaturated C═C double bond-containing polyphenylene ether resin includes a polyphenylene ether resin with 2,6-dimethyl substitution in its phenylene ether backbone. After substitution, the methyl groups form steric hindrance to prevent the oxygen atom of the ether group from forming a hydrogen bond or Van der Waals force to absorb moisture.

The unsaturated C═C double bond-containing polyphenylene ether resin includes, but not limited to, a vinylbenzyl group-containing polyphenylene ether resin with a number average molecular weight of about 1200 (such as OPE-2st 1200, available from Mitsubishi Gas Chemical Co., Inc.), a vinylbenzyl group-containing polyphenylene ether resin with a number average molecular weight of about 2200 (such as OPE-2st 2200, available from Mitsubishi Gas Chemical Co., Inc.), a vinylbenzyl group-containing polyphenylene ether resin with a number average molecular weight of about 2400 to 2800 (such as vinylbenzyl group-containing bisphenol A polyphenylene ether resin), a (meth)acryloyl group-containing polyphenylene ether resin with a number average molecular weight of about 1900 to 2300 (such as SA9000, available from Sabic), a vinyl group-containing polyphenylene ether resin with a number average molecular weight of about 2200 to 3000, or a combination thereof. Among them, the vinyl group-containing polyphenylene ether resin may include various polyphenylene ether resins disclosed in US Patent Application Publication No. 20160185904 A1, all of which are incorporated herein by reference in their entirety. The vinylbenzyl group-containing polyphenylene ether resin includes, but not limited to, vinylbenzyl group-containing biphenyl polyphenylene ether resin, vinylbenzyl group-containing bisphenol A polyphenylene ether resin, or a combination thereof.

The polyolefin resin includes, but not limited to, any one of polybutadiene, polyisoprene, styrene-butadiene copolymer, styrene-isoprene copolymer, styrene-butadiene-divinylbenzene polymer, vinyl-polybutadiene-urethane polymer, polymethylstyrene, hydrogenated polybutadiene, hydrogenated polyisoprene, hydrogenated styrene-butadiene-divinylbenzene polymer, hydrogenated styrene-butadiene copolymer, hydrogenated styrene-isoprene copolymer, styrene-ethylene-divinylbenzene polymer, styrene-ethyl vinylbenzene-divinylbenzene polymer, or a combination thereof.

The styrene-ethylvinylbenzene-divinylbenzene polymer as used herein may include various styrene-ethylvinylbenzene-divinylbenzene polymers disclosed in the US Patent Application Publication No. 20070129502A1, all of which are incorporated herein by reference in their entirety.

The benzoxazine resin includes, but not limited to, bisphenol A benzoxazine resin, bisphenol F benzoxazine resin, phenolphthalein benzoxazine resin, dicyclopentadiene benzoxazine resin, phosphorus-containing benzoxazine resin, diamine benzoxazine resin and phenyl group-modified, vinyl group-modified or allyl group-modified benzoxazine resin. The suitable commercial products may include such as products LZ-8270 (phenolphthalein benzoxazine resin), LZ-8298 (modified benzoxazine resin), LZ-82818 (bisphenol F benzoxazine resin), LZ-82919 (bisphenol A benzoxazine resin) available from Huntsman, or products KZH-5031 (allyl group-modified benzoxazine resin), KZH-5032 (phenyl group-modified benzoxazine resin) available from Kolon Industries, Inc. Among them, the diamine benzoxazine resin may be diaminodiphenylmethane benzoxazine resin, diaminodiphenyl ether benzoxazine resin, diaminodiphenyl sulfone benzoxazine resin, diaminodiphenyl sulfide benzoxazine resin or a combination thereof, but not limited thereto.

The polyester resin may be various polyester resins known in this field. The specific examples of the polyester resin include, but not limited to, dicyclopentadiene-containing polyester resin, biphenyl-containing polyester resin, and naphthalene-containing polyester resin. The specific examples may include, but not limited to, products HPC-8000-65T, HPC-8800, or HPC-8150-62T available from D.I.C. Corporation.

The phenol resin may be various phenol resins known in this field. The specific examples of the phenol resin include, but not limited to, novolac resin or phenoxy resin. Among them, the novolac resin may include, but not limited to, phenol novolac resin, o-cresol novolac resin, bisphenol A novolac resin, naphthol novolac resin, biphenyl novolac resin and dicyclopentadiene phenol resin.

The amine curing agent may be various amine curing agents known in this field. The specific examples of the amine curing agent include, but not limited to, diaminodiphenyl sulfone, diaminodiphenyl methane, diaminodiphenyl ether, diaminodiphenyl sulfide, and dicyandiamide.

The polyamide may be various polyamides known in this field. The specific examples of the polyamide include, but not limited to, various commercial polyamide resin products.

The polyimide may be various polyimides known in this field. The specific examples of the polyimide include, but not limited to, various commercial polyimide resin products.

The cyanate ester resin may be various cyanate ester resins known in this field, such as a compound with a structure of Ar—O—C═N, where Ar may be substituted or unsubstituted aryl group. In terms of improving the heat resistance of the resin composition, the specific examples of the cyanate ester resin include, but not limited to, novolac cyanate ester resin, bisphenol A cyanate ester resin, bisphenol F cyanate ester resin, dicyclopentadiene-containing cyanate ester resin, naphthalene-containing cyanate ester resin, phenolphthalein cyanate ester resin, adamantane cyanate ester resin, fluorene cyanate ester resin, or a combination thereof. Among them, the novolac cyanate ester resin may be bisphenol A novolac cyanate ester resin, bisphenol F novolac cyanate ester resin, or a combination thereof. The cyanate ester resin may be the cyanate ester resin products Primaset PT-15, PT-30, PT-30S, PT-60, PT-60S, BA-200, BA-230S, BA-3000, BA-3000S, BA-4000, BA-4000S, DT-4000, DT-7000, ULL950S, HTL-300, LVT-50, LVT-100, and LeCy available from Arxada AG.

The maleimide triazine resin may be various maleimide triazine resins known in this field. The specific examples of the maleimide triazine resin include, but not limited to, the maleimide triazine resin polymerized from maleimide resin and bisphenol A cyanate ester resin, the maleimide triazine resin polymerized from maleimide resin and bisphenol F cyanate ester resin, the maleimide triazine resin polymerized from maleimide resin and phenol novolac cyanate ester resin, maleimide triazine resin polymerized from maleimide resin and dicyclopentadiene-containing cyanate ester resin. In one embodiment, the maleimide triazine resin may be obtained by polymerizing the aforesaid maleimide resin and the aforesaid cyanate ester resin at any molar ratio. The molar ratio of maleimide resin to cyanate ester resin may range from 1:1 to 1:10, such as, but not limited to, 1:1, 1:2, 1:4, 1:6, 1:8, and 1:10.

In one embodiment, the resin composition further includes a curing accelerator, a polymerization inhibitor, a flame retardant, an inorganic filler, a surfactant, a coloring agent, a toughening agent, a solvent, or a combination thereof.

The curing accelerator may include a catalyst, such as a Lewis base or a Lewis acid. The Lewis base may include one or more of imidazole, boron trifluoride-amine complex, ethyltriphenyl phosphonium chloride, 2-methylimidazole (2 MI), 2-phenyl-1H-imidazole (2PZ), 2-ethyl-4-methylimidazole (2E4MZ), triphenylphosphine (TPP) and 4-dimethylaminopyridine (DMAP). The Lewis acid may include metal salt compounds, such as metal salt compounds of manganese, iron, cobalt, nickel, copper and zinc, or metal catalysts, such as zinc octanoate or cobalt octanoate. The curing accelerator also includes a curing initiator, such as a peroxide capable of producing free radicals. The curing initiator includes, but not limited to, dicumyl peroxide (DCP), tert-butyl peroxybenzoate, dibenzoyl peroxide (BPO), 2,5-dimethyl-2,5-di(tert-butylperoxy)-3-hexyne (DYBP), di-tert-butyl peroxide (DTBP), and bis(tert-butylperoxyisopropyl)benzene, or a combination thereof. In one embodiment, with respect to 100 parts by weight of the prepolymer of the present disclosure, resin composition of the present disclosure may further include 0.01 parts by weight to 5.0 parts by weight of the curing accelerator, preferably 0.1 parts by weight to 4.0 parts by weight of the curing accelerator, more preferably 0.1 parts by weight to 1.0 parts by weight of the curing accelerator, but not limited thereto.

The polymerization inhibitor may include, but not limited to, 1,1-diphenyl-2-picrylhydrazyl, methyl acrylonitrile, nitroxide-mediated radical, triphenylmethyl radical, metal ion radical, sulfur radical (such as including, but not limited to, dithioester), hydroquinone, 4-methoxyphenol, p-benzoquinone, phenothiazine, β-phenylnaphthylamine, 4-t-butylcatechol, methylene blue, 4,4′-butylidenebis(6-t-butyl-3-methylphenol), and 2,2′-methylenebis(4-ethyl-6-t-butyl phenol), or a combination thereof. The nitroxide-mediated radical described above may include, but not limited to, nitroxide radicals derived from cyclic hydroxylamines, such as 2,2,6,6-substituted piperidine 1-oxyl free radical or 2,2,5,5-substituted pyrrolidine 1-oxyl free radical. As a substituent, the alkyl group having less than 4 carbon atoms, such as a methyl group or an ethyl group, is preferred. The specific nitroxide-mediated radical is not limited, and may include, but not limited to, 2,2,6,6-tetramethylpiperidin-1-oxyl free radical, 2,2,6,6-tetraethylpiperidin-1-oxyl free radical, 2,2,6,6-tetramethyl-4-oxopiperidin-1-oxyl free radical, 2,2,5,5-tetramethylpyrrolidine-1-oxyl free radical, 1,1,3,3-tetramethyl-2-isoindoline oxygen radical, N,N-di-tert-butylamine oxygen free radical or the like. The nitroxide radicals may also be replaced by using stable radicals such as galvinoxyl radicals. The polymerization inhibitor suitable for the resin composition of the present disclosure may also be products derived from the polymerization inhibitor with its hydrogen atom or group substituted by other atom or group, such as products derived from a polymerization inhibitor with its hydrogen atom substituted by an amino group, a hydroxyl group, a carbonyl group or the like. For instance, in one embodiment, with respect to 100 parts by weight of the prepolymer of the present disclosure, the resin composition of the present disclosure may further include 0.001 parts by weight to 20 parts by weight of the polymerization inhibitor, preferably 0.01 parts by weight to 10 parts by weight of the polymerization inhibitor, but not limited thereto.

The flame retardant includes, but not limited to, phosphorus-containing flame retardant or bromine-containing flame retardant. The bromine-containing flame retardant preferably includes decabromodiphenyl ethane. The phosphorus-containing flame retardant preferably includes hydroquinone bis-(diphenyl phosphate), bisphenol A bis-(diphenylphosphate), tri (2-carboxyethyl)phosphine (TCEP), tris (chloroisopropyl) phosphate, trimethyl phosphate (TMP), dimethyl methyl phosphonate (DMMP), resorcinol bis(dixylenyl phosphate) (RDX, such as commercially available products PX-200, PX-201, PX-202), ammonium polyphosphate, melamine polyphosphate, phosphazene (such as commercially available products SPB-100, SPH-100, SPV-100), 9,10-dihydro-9-oxa-10-phosphaphenanthrene-10-oxide (DOPO) and its derivatives or resins (such as di-DOPO compounds), diphenylphosphine oxide (DPPO) and its derivatives or resins (such as di-DPPO compounds), melamine cyanurate, trishydroxyethyl isocyanurate, and aluminium phosphinate (such as products OP-930 and OP-935), or a combination thereof.

For instance, the flame retardant may be a flame retardant available from Katayama Chemical Industries Co., Ltd., and includes, but not limited to, V1, V2, V3, V4, V5, V7, S-2, S-4, E-4c, E-7c, E-8g, E-9g, E-10g, E-100, B-3, W-10, W-2h, W-20, W-30, W-40, OX-1, OX-2, OX-4, OX-6, OX-6+, OX-7, OX-7+, OX-13, BPE-1, BPE-3, HyP-2, API-9, CMPO, ME-20, C-1R, C-1S, C-3R, C-3S, or C-11R. The flame retardant of the present disclosure may include one or more of the above flame retardants. With respect to 100 parts by weight of the prepolymer of the present disclosure, resin composition of the present disclosure may further include 1 part by weight to 100 parts by weight of the flame retardant, preferably 5 parts by weight to 50 parts by weight of the flame retardant.

The inorganic filler includes, but not limited to, silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride, zirconium tungstate, petalite, calcined kaolin or a combination thereof. In addition, the inorganic filler the inorganic filler may be spherical (including solid sphere or hollow sphere), fibrous, plate-like, particulate, flake-like or whisker-like, and may be optionally pretreated by a silane coupling agent. In addition, the inorganic filler may be prepared by various methods, such as melting method, deflagration method, a chemical synthesis method. In addition, the particle size of the inorganic filler is not particularly limited, and its median particle size D50 may range from 1 to 45 micrometers, preferably from 1 to 15 micrometers, more preferably from 1 to 10 micrometers. In addition, the inorganic filler may be in the form of powder or slurry. In one embodiment, with respect to 100 parts by weight of the prepolymer of the present disclosure, the resin composition of the present disclosure may further include 10 parts by weight to 450 parts by weight of the inorganic filler, preferably 100 parts by weight to 400 parts by weight of the inorganic filler, but not limited thereto.

The surfactant includes, but not limited to, silane coupling agent (silane, such as siloxane compounds (siloxane)), and based on the functional group, the silane may be divided into amino silane coupling agent (amino silane), epoxide silane coupling agent (epoxide silane), vinyl silane coupling agent, hydroxyl silane coupling agent, isocyanate silane coupling agent, methacryloyloxyl silane silane coupling agent, and acryloyloxyl silane coupling agent. As used herein, the purpose of adding the surfactant is to make the inorganic filler uniformly dispersed in the resin composition. In one embodiment, with respect to 100 parts by weight of the prepolymer of the present disclosure, the resin composition of the present disclosure may further include 0.001 parts by weight to 20 parts by weight of the surfactant, preferably 0.01 parts by weight to 10 parts by weight of the surfactant, but not limited thereto.

The coloring agent may include, but not limited to, dye or pigment. In one embodiment, with respect to 100 parts by weight of the prepolymer of the present disclosure, the resin composition of the present disclosure may further include 0.001 parts by weight to 10 parts by weight of the coloring agent, preferably 0.01 parts by weight to 5 parts by weight of the coloring agent, but not limited thereto.

The toughening agent may include, but not limited to, carboxyl-terminated butadiene acrylonitrile rubber (CTBN), core-shell rubber, ethylene-propylene rubber, or a combination thereof. In one embodiment, with respect to 100 parts by weight of the prepolymer of the present disclosure, the resin composition of the present disclosure may further include 1 part by weight to 20 parts by weight of the toughening agent, preferably 3 parts by weight to 10 parts by weight of the toughening agent, but not limited thereto.

The solvent includes, but not limited to, methanol, ethanol, ethylene glycol monomethyl ether, acetone, butanone (also known as methyl ethyl ketone), methyl isobutyl ketone, cyclohexanone, nitrogen methyl pyrrolidone, toluene, xylene, methoxyethyl acetate, ethoxyethyl acetate, propoxyethyl acetate, ethyl acetate, dimethylformamide, dimethylacetamide, propylene glycol methyl ether acetate, or a mixed solvent thereof. The amount of the solvent added is intended to completely dissolve the resin and adjust the resin composition to a specific overall solid content. In one embodiment, the amount of the solvent is adjusted to allow the overall solid content of the resin composition to be 50 wt % to 85 wt %, but not limited thereto.

In addition to the aforesaid resin composition, the present disclosure further provides an article made from the resin composition described above, such as assemblies applicable to various electronic products, including but not limited to prepregs, resin films, laminates, or printed circuit boards.

The resin composition of the present disclosure may be made into a prepreg, which includes a reinforcement material and a layered structure disposed thereon. The layered structure is obtained by heating the resin composition at high temperature to a semi-cured state (B-stage). The baking temperature for making the prepreg is between 100° C. and 180° C., preferably between 120° C. and 160° C. The reinforcement material may be any one of fiber material, woven fabric, and non-woven fabric. The woven fabric preferably includes fiberglass fabrics. The types of the fiberglass fabrics are not particularly limited and may be various fiberglass fabrics applicable to printed circuit boards, such as E-glass fiber fabric, D-glass fiber fabric, S-glass fiber fabric, T-glass fiber fabric, L-glass fiber fabric, Q-glass fiber fabric, or QL-glass fiber fabric (a glass fabric of a mixed structure made of Q-glass fabric and L-glass fabric). The type of the fiberglass includes yarns and rovings, in spread form or standard form, and the end face shapes may be round or flat. The non-woven fabric preferably includes liquid crystal polymer non-woven fabric, such as polyester non-woven fabric, polyurethane non-woven fabric and so on, but the present disclosure is not limited thereto. The woven fabric may also include liquid crystal polymer woven fabric, such as polyester woven fabric, polyurethane woven fabric and so on, but the present disclosure is not limited thereto. The reinforcement material may increase the mechanical strength of the prepreg. In one preferred embodiment, the reinforcement material may be pre-treated by a silane coupling agent. The prepreg is subsequently heated and cured (C-stage) to form an insulating layer.

The resin composition of the present disclosure may be made into a resin film, which is obtained by heating and baking the resin composition to a semi-cured state. The resin composition may be optionally coated on a supporting material. The supporting material includes, but not limited to, a liquid crystal polymer film, a polytetrafluoroethylene film, a polyethylene terephthalate film (PET film), a polyimide film (PI film), a metal foil, or a resin-coated copper (RCC), followed by heating and baking to a semi-cured state so as to make the resin composition form into a resin film.

The resin composition of the present disclosure may be made into various laminates, which include at least two metal foils and at least one insulation layer disposed between the two metal foils. The insulation layer may be made by curing the resin composition at high temperature and high pressure to C-stage, in which a suitable curing temperature may be between 190° C. and 250° C., preferably between 200° C. and 240° C., a curing time may range from 90 to 180 minutes, preferably from 120 to 150 minutes, and a laminating pressure may be between 300 psi and 550 psi, preferably between 400 psi and 550 psi. The insulation layer may be formed by curing the prepreg or the resin film to C-stage. The material of the metal foil may be copper, aluminum, nickel, platinum, silver, gold, or alloy thereof, such as copper foil. In one preferred embodiment, the laminate is a copper-clad laminate.

The laminate may be further processed through a circuit processing to form a printed circuit board. One of the preparing methods for the printed circuit board of the present disclosure is described as follows: a double-sided copper-clad laminate (such as product EM-827, available from Elite Electronic Material (Kunshan) Co., Ltd.) with a thickness of 28 mil and having 1-ounce (oz) High Temperature Elongation (HTE) may be used and subject to drilling and electroplating, so as to form an electrical conduction between the upper layer copper foil and the bottom layer copper foil. Then, the upper layer copper foil and the bottom layer copper foil are etched to form an inner layer circuit board. Then, brown oxidation and roughening processes are performed on the inner layer circuit board to form uneven structures on the surface to increase roughness. Then, a copper foil, the prepreg, the inner layer circuit board, the prepreg and a copper foil are stacked in such sequence, and then heated at 190° C. to 240° C. for 90 minutes to 180 minutes by a vacuum lamination apparatus to cure the material of the insulation layer of the prepreg. Then, black oxidation, drilling, copper plating and other processes known in the field are further performed on the outmost copper foil, thereby obtaining a printed circuit board.

The article made from the resin composition includes a reinforcement material or a supporting material and a semi-cured or cured product obtained by heating and chemically cross-linking the resin composition.

In one embodiment, the article has one or more or all of the following properties:
an X-CTE at board center of less than or equal to 3.8 ppm/° C. as measured and calculated by reference to IPC-TM-650 2.4.24.5, for example, between 3.2 ppm/° C. and 3.8 ppm/° C.;
an X-CTE at board edge of less than or equal to 4.0 ppm/° C. as measured and calculated by reference to IPC-TM-650 2.4.24.5, for example, between 3.3 ppm/° C. and 4.0 ppm/° C.;
a difference between the X-CTE at board center and the X-CTE at board edge of less than or equal to 0.3 ppm/° C. as measured and calculated by reference to IPC-TM-650 2.4.24.5, for example, between 0 ppm/° C. and 0.3 ppm/° C.;
a copper foil peeling strength after copper plating of greater than or equal to 5.0 lb/in as measured by reference to IPC-TM-650 2.4.8, for example, between 5.0 lb/in and 6.4 lb/in;
a heterogeneous resin flow length of less than or equal to 2 millimeters, for example, between 1 millimeter and 2 millimeters, or even 0 millimeter;
a dimension change Cpk of a substrate after solder floating of greater than or equal to 1.35 as measured and calculated by reference to IPC-TM-650 2.4.39, for example, between 1.35 and 1.85;
a glass transition temperature of greater than or equal to 330° C. as measured by reference to IPC-TM-650 2.4.24.4, for example, between 330° C. and 350° C., or even greater than 350° C.

Raw materials below are used to prepare the prepolymer 1 to prepolymer 16 of the present disclosure and comparative prepolymer 1 to comparative prepolymer 6 of Comparative Manufacturing Examples according to the amount listed in Table 1 to Table 4, and are used to prepare the resin composition of Examples and Comparative Examples according to the amount listed in Table 5 to Table 9, and further made into testing samples or articles.

MI 1: isopropyl group and meta-arylene-containing maleimide, with the structural formula shown below, where n=1 to 10, commercially available.

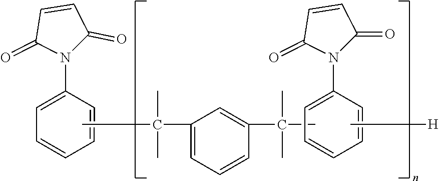

MI 2: biphenyl-containing maleimide, with the structural formula shown below, where n=1 to 10, commercially available.

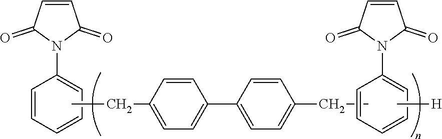

Indane MI: with the structural formula shown below, where n=0.5 to 20, commercially available.

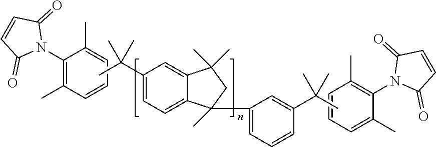

BMI-2300: poly (phenylmethane maleimide), with the structural formula shown below, where n=0.5 to 20, available from Daiwakasei Industry.

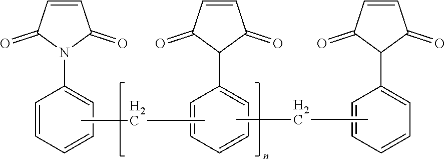

BMI-3000: maleimide resin containing an aliphatic structure with 10 to 50 carbon atoms, with the structural formula shown below, where n=1 to 10, available from Designer Molecules Inc.

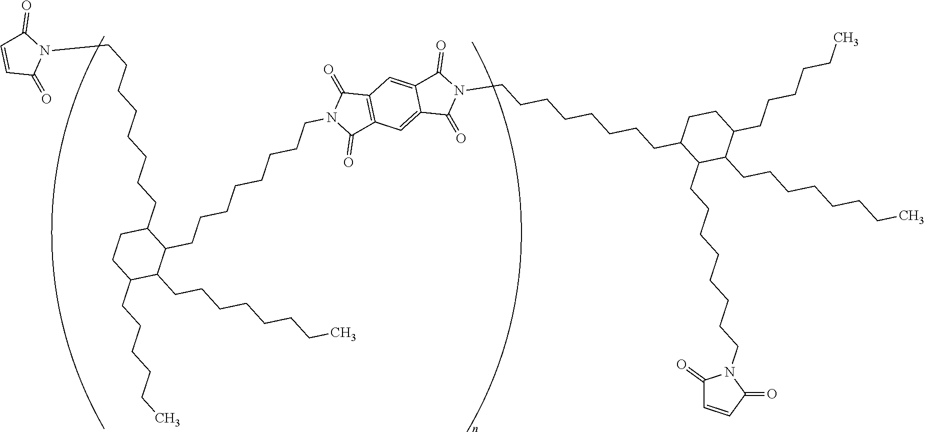

BMI-5100:3,3′-dimethyl-5,5′-diethyl-4,4′-diphenylmethane bismaleimide, available from Daiwakasei Industry.

BMI-4000: bisphenol A diphenyl ether bismaleimide, available from Daiwakasei Industry.

BMI-1000:4,4′-diphenylmethane bismaleimide, available from Daiwakasei Industry.

X-40-2670, available from Shin-Etsu Chemical Co., Ltd., with the structural 5 formula shown below:

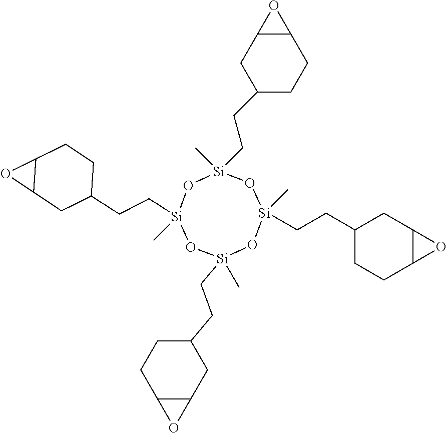 [SMILES: C[Si]1(CCC2CCC3OC3C2)O[Si](C)(CCC2CCC3OC3C2)O[Si](C)(CCC2CCC3OC3C2)O[Si](C)(CCC2CCC3OC3C2)O1]

X-40-2678, available from Shin-Etsu Silicone, with the structural formula shown below:

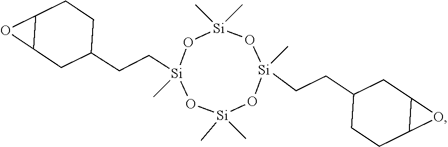 [SMILES: C[Si]1(C)O[Si](C)(CCC2CCC3OC3C2)O[Si](C)(C)O[Si](C)(CCC2CCC3OC3C2)O1]

YL9029, available from Mitsubishi Chemical, with the structural formula shown below:

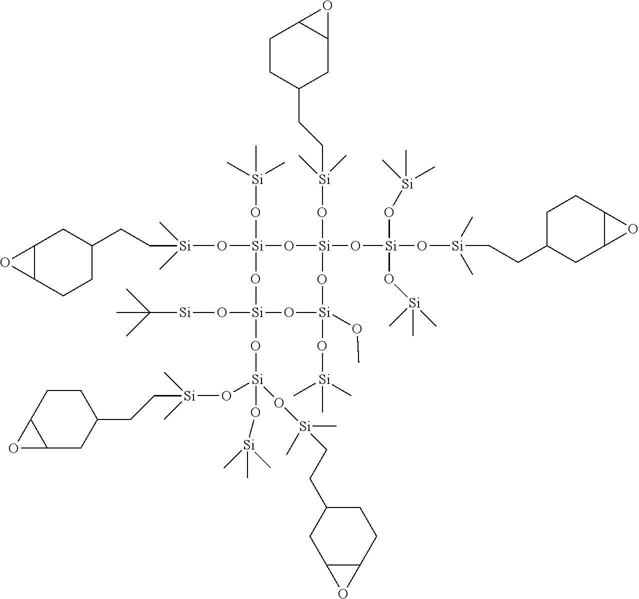

X-22-161A: aminosiloxane, with an amine equivalent of 800 g/eq, available from Shin-Etsu Chemical Co., Ltd.

X-22-161B: aminosiloxane, with an amine equivalent of 1500 g/eq, available from Shin-Etsu Chemical Co., Ltd.

KF-8012: aminosiloxane, with an amine equivalent of 2200 g/eq, available from Shin-Etsu Chemical Co., Ltd.

DABPA: diallyl bisphenol A, commercially available.

DABPD: diallyl biphenol, commercially available.

NC-3000: biphenyl epoxy resin, available from Nippon Kayaku.

SA90: hydroxyl-group containing polyphenylene ether resin, available from Saudi Basic Industries Corporation (SABIC).

Ricon 100: styrene-butadiene copolymer, available from Cray Valley SA.

Momentive coatosil MP200, obtained through hydrolysis and condensation of the following structure, where R₅ to R₇ are independently saturated alkyl groups with 1 to 5 carbon atoms, and R₈ is either an alkoxy group or a saturated alkyl group with 1 to 5 carbon atoms.

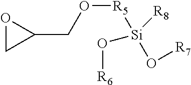

TPP: triphenylphosphine, available from Shanghai Macklin Inc.

Synthetic spherical silica slurry: median particle size D50 of spherical silica is approximately 2.5±2 micrometers, prepared by the microemulsion method. It is chemically synthesized spherical silica treated with silane coupling agents, commercially available, with a solid content of approximately 70%.

Solvent: the weight ratio of dimethylacetamide (DMAC) to butanone is 2:1, the dimethylacetamide and the butanone are commercially available. The amount of the solvent is expressed as “proper amount” (abbreviated as “PA”) which represents the amount of the solvent when the overall solid content of the resin composition is adjusted to 60% to 68% (solid content, S/C═60% to 68%).

### Manufacturing Example 1: Preparation of Prepolymer 1

100 parts by weight of a solvent (propylene glycol methyl ether acetate, PMA) and 100 parts by weight of a maleimide resin (BMI-4000) is added into a reaction vessel, followed by heated to 110° C. and stirred for 15 minutes to dissolve the maleimide resin. Then, 30 parts by weight of an active hydrogen-containing compound (amino group-modified siloxane X-22-161B) is added dropwise thereinto, followed by heated to 120° C. and stirred for 2 hours. Then, after the solution in the reaction vessel is cooled to 70° C., 3 parts by weight of an epoxy-modified cyclic siloxane (X-40-2670) is added thereinto, followed by stirred for 2 hours. The solution of prepolymer 1 may be obtained after cooling, with the conversion rate of each monomer between 10˜90%.

### Manufacturing Example 2 to Manufacturing Example 16: Preparations of Prepolymer 2 to Prepolymer 16

Referring to the preparation method of the prepolymer in Manufacturing Example 1 above, according to the amount listed in Table 1 to Table 3, a maleimide resin is added into 100 parts by weight of PMA, followed by stirred for 15 minutes at 110° C. to dissolve the maleimide resin. Then, an active hydrogen-containing compound is added dropwise thereinto, followed by heated to 120° C. and stirred for 2 hours. Then, after the solution in the reaction vessel is cooled to 70° C., an epoxy-modified cyclic siloxane is added thereinto. The reaction is continued for 2 hours. Then, the solutions of prepolymer 2 to prepolymer 16 may be obtained, with the conversion rate of each monomer between 10˜90%.

### Comparative Manufacturing Example 1: Preparation of Comparative Prepolymer 1

According to the amount listed in Table 4, a maleimide resin is added into 100 parts by weight of PMA, followed by stirred for 15 minutes at 110° C. to dissolve the maleimide resin. Then, after the solution is cooled to 70° C., an epoxy-modified cyclic siloxane is added thereinto, followed by stirred for 2 hours. Then, the solution of comparative prepolymer 1 may be obtained, with the conversion rate of each monomer between 10˜ 90%.

### Comparative Manufacturing Example 2 to Comparative Manufacturing Example 4: Preparations of Comparative Prepolymer 2 to Comparative Prepolymer 4

According to the amount listed in Table 4, a maleimide resin is added into 100 parts by weight of PMA, followed by stirred for 15 minutes at 110° C. to dissolve the maleimide resin. Then, an active hydrogen-containing compound is added dropwise thereinto, followed by heated to 120° C. and stirred for 2 hours. Then, the solutions of comparative prepolymer 2 to comparative prepolymer 4 may be obtained, with the conversion rate of each monomer between 10˜90%.

### Comparative Manufacturing Example 5: Preparation of Comparative Prepolymer 5

According to the amount listed in Table 4, 100 parts by weight of PMA and active hydrogen-containing compound are added, followed by heated to 120° C. and stirred for 2 hours. Then, after cooled to 70° C., an epoxy-modified cyclic siloxane is added thereto. The reaction is continued for 2 hours. Then, the solution of comparative prepolymer 5 may be obtained, with the conversion rate of each monomer between 10˜90%.

### Comparative Manufacturing Example 6: Preparation of Comparative Prepolymer 6

According to the amount listed in Table 4, an maleimide resin is added into 100 parts by weight of PMA, followed by stirred for 15 minutes at 110° C. to dissolve the maleimide resin. Then, an active hydrogen-containing compound is added dropwise thereinto, followed by heated to 120° C. and stirred for 2 hours. After cooled to 70° C., Momentive coatosil MP200 is added thereto. The reaction is continued for 2 hours. Then, the solution of comparative prepolymer 6 may be obtained, with the conversion rate of each monomer between 10˜90%.

TABLE 1
raw material compositions (in parts by weight) of the prepolymers of
Manufacturing Example (ME) 1 to Manufacturing Example 6

| | | ME | ME | ME | ME | ME | ME |
|---|---|---|---|---|---|---|---|
| component | | 1 | 2 | 3 | 4 | 5 | 6 |
| maleimide resin | BMI-5100 | — | — | — | — | — | — |
| | BMI-4000 | 100 | 100 | 100 | 100 | 100 | 100 |
| | BMI-1000 | — | — | — | — | — | — |
| epoxy-modified | X-40-2670 | 3 | 15 | 25 | 30 | 15 | 15 |
| cyclic siloxane | X-40-2678 | — | — | — | — | — | — |
| | YL9029 | — | — | — | — | — | — |
| active hydrogen- | X-22-161A | — | — | — | — | — | — |
| containing | X-22-161B | 30 | 30 | 30 | 30 | 5 | 10 |
| compound | KF-8012 | — | — | — | — | — | — |
| | DABPA | — | — | — | — | — | — |
| | DABPD | — | — | — | — | — | — |

| | | | | | | |
|---|---|---|---|---|---|---|
| Momentive coatosil MP200 | — | — | — | — | — | — |

TABLE 2
raw material compositions (in parts by weight) of the
prepolymers of ME 7 to ME 12

| | | | | ME | ME | ME | ME |
|---|---|---|---|---|---|---|---|
| component | | ME 7 | ME 8 | 9 | 10 | 11 | 12 |
| maleimide resin | BMI-5100 | — | — | 50 | — | — | — |
| | BMI-4000 | 100 | 100 | | 100 | 50 | 100 |
| | BMI-1000 | — | — | 50 | — | 50 | — |
| epoxy-modified | X-40-2670 | 15 | 15 | 5 | 20 | 8 | 15 |
| cyclic siloxane | X-40-2678 | — | — | 5 | — | — | — |
| | YL9029 | — | — | — | — | 5 | — |
| active hydrogen- | X-22-161A | — | — | 35 | — | — | — |
| containing | X-22-161B | 40 | 45 | — | — | — | 25 |
| compound | KF-8012 | — | — | — | — | — | — |
| | DABPA | — | — | — | 10 | 10 | 5 |
| | DABPD | — | — | — | — | — | — |

| | | | | | | |
|---|---|---|---|---|---|---|
| Momentive coatosil MP200 | — | — | — | — | — | — |

TABLE 3
raw material compositions (in parts by weight)
of the prepolymers of ME 13 to ME 16

| | | ME | ME | ME | ME |
|---|---|---|---|---|---|
| component | | 13 | 14 | 15 | 16 |
| maleimide resin | MI 1 | — | — | — | 3 |
| | MI 2 | — | — | 5 | 2 |
| | indane MI | — | — | — | 2 |
| | BMI-2300 | — | — | 5 | 30 |
| | BMI-3000 | — | — | — | 3 |
| | BMI-5100 | — | — | 10 | 20 |
| | BMI-4000 | 100 | 100 | 45 | 30 |
| | BMI-1000 | — | — | 45 | 50 |
| epoxy-modified cyclic | X-40-2670 | 15 | 15 | 10 | 15 |
| siloxane | X-40-2678 | — | — | — | — |
| | YL9029 | — | — | — | — |
| active hydrogen- | X-22-161A | — | — | 10 | — |
| containing compound | X-22-161B | 15 | 5 | 3 | 15 |
| | KF-8012 | — | — | 2 | 5 |
| | DABPA | 15 | 25 | 4 | 2 |
| | DABPD | — | — | 6 | 3 |

| | | | | |
|---|---|---|---|---|
| Momentive coatosil MP200 | — | — | — | — |

TABLE 4
raw material compositions (in parts by weight) of the comparative
prepolymers of Comparative Manufacturing Example (CME) 1
to Comparative Manufacturing Example 6

| | | | | CME | CME | CME | CME |
|---|---|---|---|---|---|---|---|
| component | | CME 1 | CME 2 | 3 | 4 | 5 | 6 |
| maleimide | BMI-5100 | — | — | — | — | — | — |
| resin | BMI-4000 | 100 | 100 | 100 | 100 | — | 100 |
| | BMI-1000 | — | — | — | — | — | — |
| epoxy- | X-40-2670 | 15 | — | — | — | 15 | — |
| modified | X-40-2678 | — | — | — | — | — | — |
| cyclic | YL9029 | — | — | — | — | — | — |
| siloxane | | | | | | | |
| active | X-22-161A | — | — | — | — | — | — |
| hydrogen- | X-22-161B | — | 30 | — | 15 | 30 | 25 |
| containing | KF-8012 | — | — | — | — | — | — |
| compound | DABPA | — | — | 10 | 15 | — | 5 |
| | DABPD | — | — | — | — | — | — |

| | | | | | | |
|---|---|---|---|---|---|---|
| Momentive coatosil MP200 | — | — | — | — | — | 15 |

TABLE 5
The components (in parts by weight) and the property testing results of
the resin composition of Examples E1 to E6

| component | | E1 | E2 | E3 | E4 | E5 | E6 |
|---|---|---|---|---|---|---|---|
| prepolymer 1 | | 133 | — | — | — | — | — |
| prepolymer 2 | | — | 145 | — | — | — | — |
| prepolymer 3 | | — | — | 155 | — | — | — |
| prepolymer 4 | | — | — | — | 160 | — | — |
| prepolymer 5 | | — | — | — | — | 120 | |
| prepolymer 6 | | — | — | — | — | — | 125 |
| prepolymer 7 | | — | — | — | — | — | — |
| prepolymer 8 | | — | — | — | — | — | — |
| prepolymer 9 | | — | — | — | — | — | — |
| prepolymer 10 | | — | — | — | — | — | — |
| prepolymer 11 | | — | — | — | — | — | — |
| prepolymer 12 | | — | — | — | — | — | — |
| prepolymer 13 | | — | — | — | — | — | — |
| prepolymer 14 | | — | — | — | — | — | — |
| prepolymer 15 | | — | — | — | — | — | — |
| prepolymer 16 | | — | — | — | — | — | — |
| NC-3000 | | — | — | — | — | — | — |
| SA90 | | — | — | — | — | — | — |
| Ricon 100 | | — | — | — | — | — | — |
| curing | TPP | 0.5 | 0.5 | 0.5 | 0.5 | 0.5 | 0.5 |
| accelerator | | | | | | | |
| inorganic | synthetic | 250 | 250 | 250 | 250 | 250 | 250 |
| filler | spherical | | | | | | |
| | silica slurry | | | | | | |
| solvent | DMAC/ | PA | PA | PA | PA | PA | PA |
| | butanone | | | | | | |
| properties | unit | E1 | E2 | E3 | E4 | E5 | E6 |
| X-CTE at | ppm/° C. | 3.4 | 3.2 | 3.4 | 3.8 | 3.8 | 3.5 |
| board center | | | | | | | |
| X-CTE at | ppm/° C. | 3.6 | 3.3 | 3.3 | 4.0 | 3.7 | 3.7 |
| board edge | | | | | | | |
| a difference | ppm/° C. | 0.2 | 0.1 | 0.1 | 0.2 | 0.1 | 0.2 |
| between | | | | | | | |
| the X-CTE | | | | | | | |
| at board center | | | | | | | |
| and at | | | | | | | |
| board edge | | | | | | | |
| P/S after | lb/in | 5.2 | 5.8 | 6.1 | 5.9 | 6.1 | 6.0 |
| copper plating | | | | | | | |
| heterogeneous | mm | 0 | 0 | 0 | 0 | 0 | 0 |
| resin flow | | | | | | | |
| length | | | | | | | |
| dimension | — | 1.55 | 1.77 | 1.82 | 1.35 | 1.44 | 1.62 |
| stability | | | | | | | |
| after solder | | | | | | | |
| floating | | | | | | | |
| Tg | ° C. | O | O | O | O | O | O |

TABLE 6
The components (in parts by weight) and the property testing results of
the resin composition of Examples E7 to E12

| component | | E7 | E8 | E9 | E10 | E11 | E12 |
|---|---|---|---|---|---|---|---|
| prepolymer 1 | | — | — | — | — | — | — |
| prepolymer 2 | | — | — | — | — | — | — |
| prepolymer 3 | | — | — | — | — | — | — |
| prepolymer 4 | | — | — | — | — | — | — |
| prepolymer 5 | | — | — | — | — | — | — |
| prepolymer 6 | | — | — | — | — | — | — |
| prepolymer 7 | | 155 | — | — | — | — | — |
| prepolymer 8 | | — | 160 | — | — | — | — |
| prepolymer 9 | | — | — | 145 | — | — | — |
| prepolymer 10 | | — | — | — | 130 | — | — |
| prepolymer 11 | | — | — | — | — | 128 | — |
| prepolymer 12 | | — | — | — | — | — | 145 |
| prepolymer 13 | | — | — | — | — | — | — |
| prepolymer 14 | | — | — | — | — | — | — |
| prepolymer 15 | | — | — | — | — | — | — |
| prepolymer 16 | | — | — | — | — | — | — |
| NC-3000 | | — | — | — | — | — | — |
| SA90 | | — | — | — | — | — | — |
| Ricon 100 | | — | — | — | — | — | — |
| curing | TPP | 0.5 | 0.5 | 1.0 | 0.5 | 0.1 | 0.5 |
| accelerator | | | | | | | |
| inorganic | synthetic | 250 | 250 | 250 | 250 | 200 | 250 |
| filler | spherical | | | | | | |
| | silica slurry | | | | | | |
| solvent | DMAC/ | PA | PA | PA | PA | PA | PA |
| | butanone | | | | | | |
| properties | unit | E7 | E8 | E9 | E10 | E11 | E12 |
| X-CTE at | ppm/° C. | 3.2 | 3.7 | 3.2 | 3.8 | 3.5 | 3.5 |
| board center | | | | | | | |
| X-CTE at | ppm/° C. | 3.3 | 4.0 | 3.3 | 3.8 | 3.6 | 3.4 |
| board edge | | | | | | | |
| a difference | ppm/° C. | 0.1 | 0.3 | 0.1 | 0.0 | 0.1 | 0.1 |
| between | | | | | | | |
| the X-CTE at | | | | | | | |
| board center | | | | | | | |
| and at | | | | | | | |
| board edge | | | | | | | |
| P/S after | lb/in | 5.2 | 5.0 | 5.5 | 5.9 | 5.9 | 6.0 |
| copper plating | | | | | | | |
| heterogeneous | mm | 0 | 1~2 | 0 | 0 | 0 | 0 |
| resin flow | | | | | | | |
| length | | | | | | | |
| dimension | — | 1.55 | 1.37 | 1.48 | 1.52 | 1.55 | 1.72 |
| stability | | | | | | | |
| after solder | | | | | | | |
| floating | | | | | | | |
| Tg | | O | Δ | O | O | O | O |

TABLE 7
The components (in parts by weight) and the property testing
results of the resin composition of Examples E13 to E16

| component | | E13 | E14 | E15 | E16 |
|---|---|---|---|---|---|
| prepolymer 1 | | — | — | — | — |
| prepolymer 2 | | — | — | — | — |
| prepolymer 3 | | — | — | — | — |
| prepolymer 4 | | — | — | — | — |
| prepolymer 5 | | — | — | — | — |
| prepolymer 6 | | — | — | — | — |
| prepolymer 7 | | — | — | — | — |
| prepolymer 8 | | — | — | — | — |
| prepolymer 9 | | — | — | — | — |
| prepolymer 10 | | — | — | — | — |
| prepolymer 11 | | — | — | — | — |
| prepolymer 12 | | — | — | — | — |
| prepolymer 13 | | 145 | — | — | — |
| prepolymer 14 | | — | 145 | — | — |
| prepolymer 15 | | — | — | 145 | — |
| prepolymer 16 | | — | — | — | 180 |
| NC-3000 | | — | — | 5 | 3 |
| SA90 | | — | — | 5 | 2 |
| Ricon 100 | | — | — | — | 1 |
| curing accelerator | TPP | 0.5 | 0.5 | 0.5 | 0.5 |
| inorganic filler | synthetic spherical | 250 | 250 | 350 | 400 |
| | silica slurry | | | | |
| solvent | DMAC/butanone | PA | PA | PA | PA |

| properties | unit | E13 | E14 | E15 | E16 |
|---|---|---|---|---|---|
| X-CTE at board center | ppm/° C. | 3.6 | 3.8 | 3.3 | 3.6 |
| X-CTE at board edge | ppm/° C. | 3.6 | 3.9 | 3.3 | 3.5 |
| a difference between | ppm/° C. | 0.0 | 0.1 | 0.0 | 0.1 |
| the X-CTE at board | | | | | |
| center and at board edge | | | | | |
| P/S after copper plating | lb/in | 6.3 | 6.4 | 6.1 | 6.3 |
| heterogeneous resin | mm | 0 | 0 | 0 | 0 |
| flow length | | | | | |
| dimension stability | — | 1.63 | 1.46 | 1.85 | 1.77 |
| after solder floating | | | | | |
| Tg | ° C. | ◯ | ◯ | ◯ | ◯ |

TABLE 8
The components (in parts by weight) and the property testing
results of the resin composition of
Comparative Examples C1 to C6

| | | C | C | C | C | C | C |
|---|---|---|---|---|---|---|---|
| component | | 1 | 2 | 3 | 4 | 5 | 6 |
| comparative | | 115 | — | — | — | — | — |
| prepolymer 1 | | | | | | | |
| comparative | | — | 130 | — | — | — | — |
| prepolymer 2 | | | | | | | |
| comparative | | — | — | 110 | — | — | — |
| prepolymer 3 | | | | | | | |
| comparative | | — | — | — | 130 | — | — |
| prepolymer 4 | | | | | | | |
| comparative | | — | — | — | — | 45 | — |
| prepolymer 5 | | | | | | | |
| comparative | | — | — | — | — | — | — |
| prepolymer 6 | | | | | | | |
| BMI-4000 | | — | — | — | — | 100 | 100 |
| X-40-2670 | | — | 15 | 20 | 15 | — | 15 |
| X-22-161B | | 30 | — | — | — | — | 15 |
| DABPA | | — | — | — | — | — | 15 |
| curing | TPP | 0.5 | 0.5 | 0.5 | 0.5 | 0.5 | 0.5 |
| accelerator | | | | | | | |
| inorganic | synthetic | 250 | 250 | 250 | 250 | 250 | 250 |
| filler | spherical | | | | | | |
| | silica | | | | | | |
| | slurry | | | | | | |
| solvent | DMAC/ | PA | PA | PA | PA | PA | PA |
| | butanone | | | | | | |
| | | C | C | C | C | C | C |
| properties | unit | 1 | 2 | 3 | 4 | 5 | 6 |
| X-CTE at | ppm/ | 4.8 | 3.7 | 4.3 | 4.0 | 5.2 | 5.5 |
| board | ° C. | | | | | | |
| center | | | | | | | |
| X-CTE at | ppm/ | 4.1 | 3.3 | 3.8 | 3.5 | 4.5 | 4.5 |
| board edge | ° C. | | | | | | |
| a difference | ppm/ | 0.7 | 0.4 | 0.5 | 0.5 | 0.7 | 1.0 |
| between | ° C. | | | | | | |
| the | | | | | | | |
| X-CTE at | | | | | | | |
| board | | | | | | | |
| center | | | | | | | |
| and at | | | | | | | |
| board edge | | | | | | | |
| P/S after | lb/in | 3.6 | 4.8 | 4.9 | 5.1 | 3.5 | 3.9 |
| copper | | | | | | | |
| plating | | | | | | | |
| hetero- | mm | >50 | 10~ | 15~ | 15~ | 10~ | >50 |
| geneous | | | 20 | 30 | 20 | 25 | |
| resin flow | | | | | | | |
| length | | | | | | | |
| dimension | — | 0.96 | 1.31 | 1.28 | 1.25 | 1.20 | 0.72 |
| stability | | | | | | | |
| after | | | | | | | |
| solder | | | | | | | |
| floating | | | | | | | |
| Tg | ° C. | X | O | O | O | X | X |

TABLE 9
The components (in parts by weight) and the property testing results
of the resin composition of Comparative Examples C7 to C9

| component | | C7 | C8 | C9 |
|---|---|---|---|---|
| comparative prepolymer 1 | | — | — | — |
| comparative prepolymer 2 | | — | — | — |
| comparative prepolymer 3 | | — | — | — |
| comparative prepolymer 4 | | — | — | — |
| comparative prepolymer 5 | | — | — | — |
| comparative prepolymer 6 | | — | — | 145 |
| BMI-4000 | | 100 | 100 | — |
| X-40-2670 | | 20 | 15 | — |
| X-22-161B | | — | 30 | — |
| DABPA | | 10 | — | — |
| curing accelerator | TPP | 0.5 | 0.5 | 0.5 |
| inorganic filler | synthetic spherical silica slurry | 250 | 250 | 250 |
| solvent | DMAC/butanone | PA | PA | PA |

| properties | unit | C7 | C8 | C9 |
|---|---|---|---|---|
| X-CTE at board center | ppm/° C. | 5.8 | 5.3 | 4.5 |
| X-CTE at board edge | ppm/° C. | 4.5 | 4.2 | 3.9 |
| a difference between | ppm/° C. | 1.3 | 1.1 | 0.6 |
| the X-CTE at board | | | | |
| center and at board edge | | | | |
| P/S after | lb/in | 4.0 | 3.3 | 5.5 |
| copper plating | | | | |
| heterogeneous resin | mm | 20~35 | >50 | 5~10 |
| flow length | | | | |
| dimension stability | — | 0.65 | 0.79 | 1.25 |
| after solder floating | | | | |
| Tg | ° C. | X | X | X |

In the present disclosure, the property tests of the Examples and Comparative Examples are performed by preparing test specimens (samples) in the following manner and then performing the tests under specific test conditions.
(1) Prepreg (PP): The resin compositions respectively selected from Examples and 5 Comparative Examples are mixed uniformly to form varnish. The varnish is loaded into an impregnation tank, and the fiberglass fabric (such as 2116 L-glass fiber fabric or 1080 L-glass fiber fabric, all available from Asahi) is then immersed into the impregnation tank described above to adhere the resin composition onto the fiberglass fabric, followed by heating at 150° C. to 170° C. to a semi-cured stage (B-Stage) to obtain a prepreg. The resin content of the prepreg made from the 1080 L-glass fiber fabric is approximately 70%; the resin content of the prepreg made from the 2116 L-glass fiber fabric is approximately 55%.
(2) Copper-clad laminate I (8-ply, formed by lamination of eight prepregs): Two HVLP copper foils with a thickness of 18 μm and eight prepregs obtained from 2116 L-glass fiber fabrics impregnated with each specimen (each Example or Comparative Example) are prepared. Each prepreg has a resin content of about 55%. One copper foil, eight prepregs and one copper foil are stacked in such order, followed by lamination under vacuum at 500 psi and 240° C. for 2 hours to form a copper-clad laminate I (8-ply).
(3) Copper-free laminate I (8-ply, formed by lamination of eight prepregs): The copper-clad laminate I (8-ply) described above is etched to remove the copper foils on both sides to obtain a copper-free laminate I (8-ply).
(4) Copper-clad laminate II (8-ply, formed by lamination of eight prepregs): Two carrier copper foils (MT18-EX, available from MITSUI COPPER FOIL) and eight 8 prepregs obtained from 2116 L-glass fiber fabrics impregnated with each specimen (each Example or Comparative Example) are prepared. Each prepreg has a resin content of about 55%. One copper foil, eight prepregs and one copper foil are stacked in such order, followed by lamination under vacuum at 500 psi and 240° C. for 2 hours to form a copper-clad laminate II (8-ply).
(5) Copper-free laminate III (1-ply, formed by lamination of one prepreg): Two VLP copper foils with a thickness of 12 μm and one prepreg obtained from 2116 L-glass fiber fabrics impregnated with each specimen (each Example or Comparative Example) are prepared. One copper foil, one prepreg and one copper foil are stacked in such order, followed by lamination under vacuum at 500 psi and 240° C. for 2 hours to form a copper-clad laminate III (1-ply). The copper-clad laminate III (1-ply) is etched to remove the copper foils on both sides to obtain a copper-free laminate III (1-ply).

Each testing method and the properties are described below.
1. Coefficient of thermal expansion at X-axis (X-CTE) at board center and at borad edge and uniformity of coefficient of thermal expansion at X-axis (X-CTE uniformity)

Cut out three strips of 3 mm×24 mm specimens at the board center and edge areas of the copper-free laminate I (8-ply), respectively, and the specimens are subjected to thermal mechanical analysis (TMA) by reference to IPC-TM-650 2.4.24.5, followed by heated at a rate of 10° C. per minute from 35° C. to 330° C. The coefficient of thermal expansion at X-axis (in ppm/° C.) of each specimen within a temperature range of 40° C. to 125° C. is measured. The average coefficient of thermal expansion at X-axis for the three specimens cut from the center area is denoted as A1 (i.e., coefficient of thermal expansion at X-axis at borad center), the average coefficient of thermal expansion at X-axis for the three specimens cut from the edge area is denoted as A2 (i.e., coefficient of thermal expansion at X-axis at borad edge), and a difference between the coefficient of thermal expansion at X-axis at board center and at board edge is |A1-A2|. The lower the difference between the coefficient of thermal expansion at X-axis at board center and at board edge is, the better the coefficient of thermal expansion at X-axis uniformity is.
2. Copper foil peeling strength after copper plating (peeling strength, P/S)

The protective copper foil on the surface of the copper-clad laminate II (8-ply) is peeled off, and the base copper of the inner layer is electroplated until the thickness of the surface copper foil increases to 35 μm, forming an evaluation laminate I. The evaluation laminate I is cut into a rectangular specimen with a width of 24 mm and a length of greater than 60 mm. The surface copper foil is etched, leaving only a strip-shaped copper foil with a width of 3.18 mm and a length greater than 60 mm. Using a universal tensile tester, measurements are conducted at room temperature (approximately 25° C.) by reference to IPC-TM-650 2.4.8 to determine the force (in lb/in) required to peel the copper foil from the surface of the insulation layer.
3. Heterogeneous resin flow length

The copper-clad laminate I (8-ply) is selected as an inner layer laminte. The surface of the inner layer laminte is subjected to a brown oxidation. Further, four 10 cm×10 cm square sections are evenly cut from the previously mentioned 1080 prepreg. The cut prepreg is then stacked onto the inner layer laminte that has been subjected to a brown oxidation, followed by covering the prepreg surface with a 12 μm thick HVLP copper foil, followed by lamination under vacuum at 500 psi and 200° C. for 2 hours. The laminated three-layer board is fully etched, and a visual inspection is conducted to check for heterogeneous resin flow (where heterogeneous resin flow appears as uneven coloration or streaks). The heterogeneous resin flow length is measured and recorded in millimeters.
4. Dimension stability after solder floating

The copper-free laminate III (1-ply) is selected as a specimen, with 20 pieces per group. A drill bit is used to perform nine-point drilling in a uniform 3×3 grid pattern on the laminate. Then, an X-ray measuring machine is used to measure the distance a between the holes. Then, the laminate is subjected to solder floating treatment (by placing it horizontally on the molten solder surface of a constant-temperature 288° C. solder bath; each cycle involves floating the laminate on the solder for 10 seconds, then removing it and cooling it for 30 seconds. This process is repeated 20 times.) Then, the hole-to-hole distance b is measured again. The shrinkage rate=(a−b)/a×100%. The shrinkage rate after solder floating is statistically analyzed and the complex process capability index (Cpk) is calculated. The higher the Cpk, the better the control of the dimension stability after solder floating.
5. Glass transition temperature (Tg)

The copper-free laminate I (8-ply) is selected as a specimen. The glass transition temperature (in° C.) of each specimen is measured by dynamic mechanical analyzer (DMA) by reference to IPC-TM-650 2.4.24.4. The measurement temperature range is from 50° C. to 400° C., at a heating rate of 2° C./min. If the measured Tg is less than 330° C., it is considered unqualified and marked as X. If the measured Tg is between 330° C. and 350° C., it is considered qualified and marked as Δ. If the measured Tg is greater than 350° C., it is considered excellent and marked as ◯.

By referring to the property testing results in Table 5 to Table 9, the following phenomena can be clearly observed:
From Examples E1 to E16, it can be confirmed that the resin composition of the present disclosure and article made therefrom can improve one or more aspects, including X-CTE at board center, X-CTE at board edge, X-CTE uniformity, P/S after copper plating, heterogeneous resin flow length, dimension stability after solder floating, glass transition temperature.

In Examples E1 to E7 and Examples E9 to E16, the amount of active hydrogen-containing compound used in the prepolymer ranges from 5 to 40 parts by weight. In Example E8, the amount of active hydrogen-containing compound used in the prepolymer is 45 parts by weight. Compared to 45 parts by weight of active hydrogen-containing compound used in the prepolymer, when active hydrogen-containing compound used in the prepolymer ranges from 5 to 40 parts by weight, the resin composition and article made therefrom achieve significant improvements, at least in the aspects of X-CTE uniformity, P/S after copper plating, heterogeneous resin flow length, and glass transition temperature.

In Examples E1 to E3 and Examples E5 to E16, the amount of epoxy-modified cyclic siloxane used in the prepolymer ranges from 3 to 25 parts by weight. In Example E4, the amount of epoxy-modified cyclic siloxane used in the prepolymer is 30 parts by weight. Compared to 30 parts by weight of the epoxy-modified cyclic siloxane used in the prepolymer, when epoxy-modified cyclic siloxane used in the prepolymer ranges from 3 to 25 parts by weight, the resin composition and article made therefrom achieve significant improvements, at least in the aspect of dimension stability after solder floating.

Although the resin compositions in Comparative Examples C6 to C8 contain maleimide resin, epoxy-modified cyclic siloxane, and active hydrogen-containing compound, these three components were not prepolymerized. The resin compositions in Comparative Examples C1 to C5 contain prepolymers made by prepolymerizing any two of maleimide resin, epoxy-modified cyclic siloxane, and active hydrogen-containing compound. A comparison of Examples E1 to E16 with Comparative Examples C1 to C5 and C6 to C8 shows that with respect to the cases where the three components (maleimide resin, epoxy-modified cyclic siloxane, and active hydrogen-containing compound) are not prepolymerized or partially prepolymerized, the resin compositions containing the prepolymer of the present disclosure achieve improvements, at least in the aspects of X-CTE uniformity, heterogeneous resin flow length, and dimension stability after solder floating.

The prepolymer in the resin composition of Comparative Example C9 is obtained by prepolymerizing maleimide resin with other epoxy-modified siloxane (Momentive coatosil MP200) and active hydrogen-containing compound. A comparison of Examples E1 to E16 with Comparative Examples C9 shows that with respect to the prepolymer obtained by replacing epoxy-modified cyclic siloxane with other epoxy-modified siloxane for prepolymerization, the resin compositions containing the prepolymer of the present disclosure achieve improvements, at least in the aspects of X-CTE at board center, X-CTE uniformity, heterogeneous resin flow length, dimension stability after solder floating, and glass transition temperature.

The above detailed description is merely illustrative in nature and is not intended to limit the embodiments of the present disclosure or the application and uses thereof. As used herein, the term “example” means “serving as an example, instance, or illustration.” Unless otherwise specified, any exemplary embodiments described herein is not necessarily to be interpreted as more preferred or advantageous than other embodiments.

Moreover, although at least one exemplary example or comparative example has been presented in the foregoing detailed description, it should be understood that there may be a vast number of variations. It should also be understood that the examples described herein are not intended to limit the scope, use, or configuration of the claimed technical solutions in any way. Instead, the aforementioned embodiments provide a convenient guide for those skilled in the art to implement one or more of the described embodiments and their equivalent forms. Furthermore, the claims include known equivalent forms and all foreseeable equivalent forms at the time of filing this patent application.

What is claimed is:

1. A prepolymer, characterized in that the prepolymer is obtained from a mixture through a prepolymerization reaction, wherein the mixture comprises:
(a) a maleimide resin,
(b) an epoxy-modified cyclic siloxane, and
(c) an active hydrogen-containing compound,
wherein the active hydrogen-containing compound comprises an aminosiloxane, a diallyl bisphenol, or a combination thereof.

2. The prepolymer of claim 1, characterized in that with respect to 100 parts by weight of maleimide resin, an amount of the epoxy-modified cyclic siloxane ranges from 3 to 30 parts by weight, and an amount of the active hydrogen-containing compound ranges from 5 to 45 parts by weight.

3. The prepolymer of claim 1, characterized in that with respect to 100 parts by weight of maleimide resin, an amount of the epoxy-modified cyclic siloxane ranges from 3 to 25 parts by weight, and an amount of the active hydrogen-containing compound ranges from 5 to 40 parts by weight.

4. The prepolymer of claim 1, characterized in that a conversion rate of the prepolymerization reaction ranges from 1 to 99%; and/or a weight average molecular weight of the prepolymer ranges from 3000 to 5000.

5. The prepolymer of claim 1, characterized in that the maleimide resin comprises an oligomeric maleimide resin, a non-oligomeric maleimide resin, or a combination thereof.

6. The prepolymer of claim 1, characterized in that the maleimide resin comprises 70 to 100 wt % non-oligomeric maleimide resin and 0 to 30 wt % oligomeric maleimide resin.

7. The prepolymer of claim 5, characterized in that the oligomeric maleimide resin comprises a poly (phenylmethane maleimide), an indane-containing maleimide, an isopropyl group and meta-arylene-containing maleimide, a biphenyl alkylene-containing maleimide, a maleimide containing an aliphatic structure with 10 to 50 carbon atoms, or a combination thereof.

8. The prepolymer of claim 5, characterized in that the non-oligomeric maleimide resin comprises a 4,4′-diphenylmethane bismaleimide, a bisphenol A diphenyl ether bismaleimide, a 3,3′-dimethyl-5,5′-diethyl-4,4′-diphenylmethane bismaleimide, a 3,3′-dimethyl-5,5′-dipropyl-4,4′-diphenylmethane bismaleimide, an meta-phenylene bismaleimide, a 4-methyl-1,3-phenylene bismaleimide, a 1,6-bismaleimide-(2,2,4-trimethyl) hexane, an N-2,3-xylylmaleimide, an N-2,6-xylylmaleimide, an N-phenylmaleimide, a vinyl benzyl maleimide, or a combination thereof.

9. The prepolymer of claim 1, characterized in that the epoxy-modified cyclic siloxane comprises a structure represented by Formula (1): 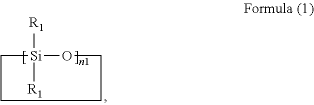
wherein in Formula (1), n1 is an integer ranging from 3 to 6, multiple R₁ groups may be the same or different, at least one of the multiple R₁ groups is a group containing an epoxy group, and each R₁ group is independently C1 to C3 alkyl group, 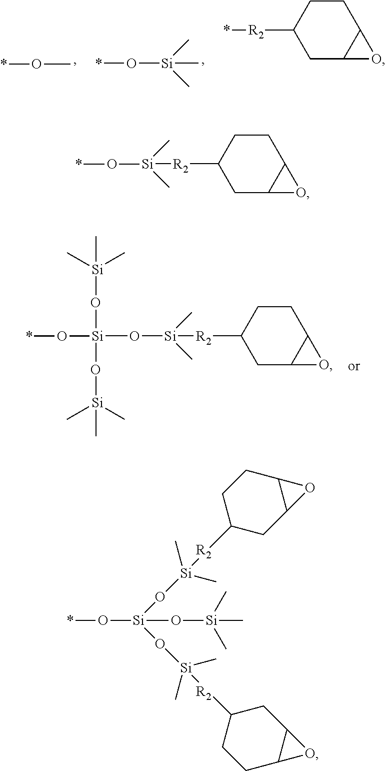
wherein, each R₂ group is independently C1 to C3 alkyl group.

10. The prepolymer of claim 1, characterized in that the epoxy-modified cyclic siloxane comprises any one of a structure represented by Formula (1-1) to Formula (1-3), or a combination thereof:

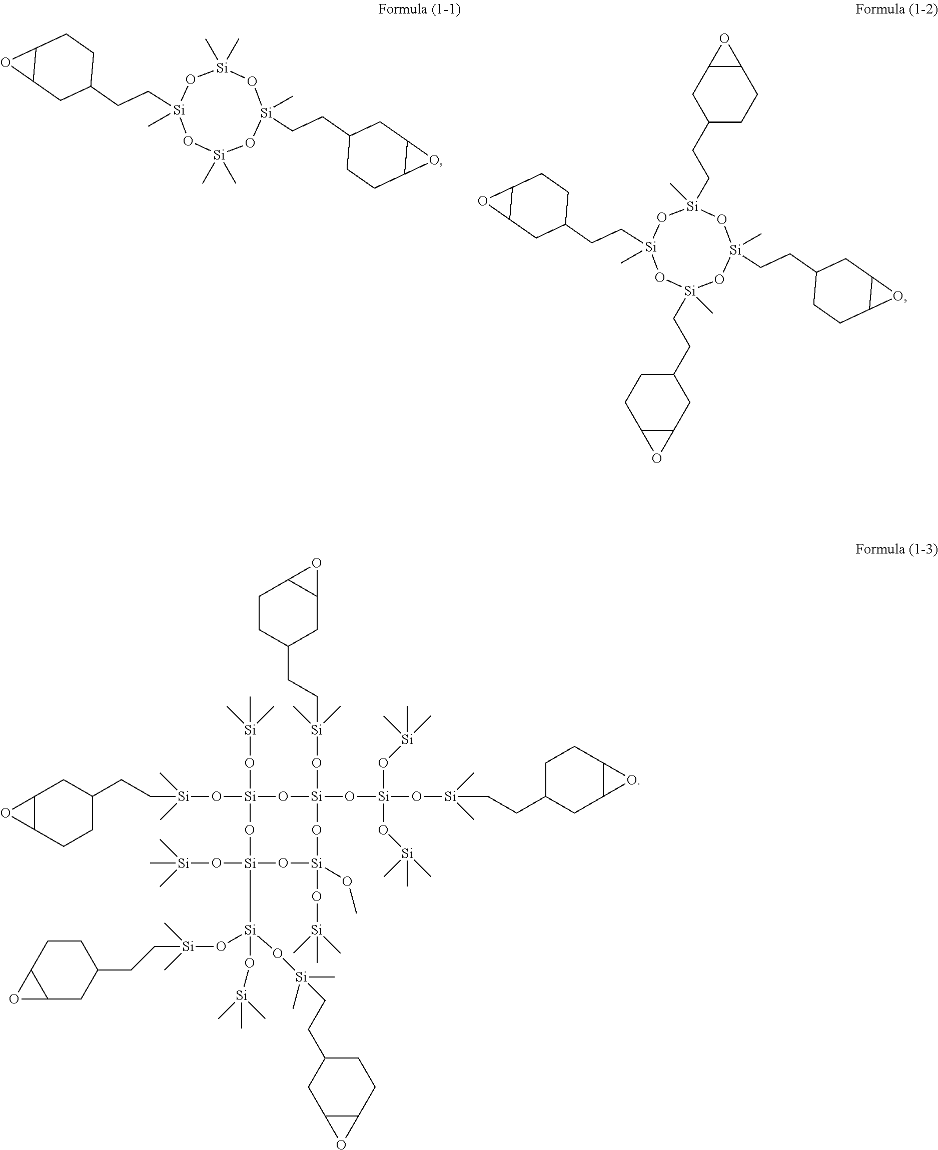 [SMILES: C[Si]1(C)O[Si](C)(CCC2CCC3OC3C2)O[Si](C)(C)O[Si](C)(CCC2CCC3OC3C2)O1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O1 ; CO[Si]1(O[Si](C)(C)C)O[Si](C[Si](O[Si](C)(C)C)(O[Si](C)(C)CCC2CCC3OC3C2)O[Si](C)(C)CCC2CCC3OC3C2)(O[Si](C)(C)C)O[Si](O[Si](C)(C)C)(O[Si](C)(C)CCC2CCC3OC3C2)O[Si](O[Si](C)(C)CCC2CCC3OC3C2)(O[Si](O[Si](C)(C)C)(O[Si](C)(C)C)O[Si](C)(C)CCC2CCC3OC3C2)O1]

11. The prepolymer of claim 1, characterized in that the aminosiloxane comprises a structure represented by Formula (2): 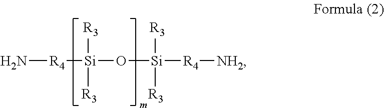
wherein in Formula (2), multiple R₃ groups may be the same or different, each R₃ group is independently alkyl group, phenyl group, or alkoxy group, multiple R₄ groups may be the same or different, each R₄ group is independently alkylene, alkenylene, alkynylene, arylene, or —O—, and m is an integer ranging from 1 to 100.

12. The prepolymer of claim 1, characterized in that the diallyl bisphenol comprises a diallyl bisphenol A, a diallyl bisphenol F, a diallyl biphenol, or a combination thereof.

13. A resin composition, characterized in that the resin composition comprises the prepolymer of claim 1.

14. The resin composition of claim 13, characterized in that the resin composition further comprises a crosslinking agent, an organic silicone resin, an epoxy resin, a maleimide resin, or a combination thereof.

15. The resin composition of claim 13, characterized in that the resin composition further comprises a polyphenylene ether resin, a polyolefin resin, a benzoxazine resin, a polyester resin, a phenol resin, an amine curing agent, a polyamide, a polyimide, a cyanate ester resin, a maleimide triazine resin, or a combination thereof.

16. The resin composition of claim 13, characterized in that the resin composition further comprises a curing accelerator, a polymerization inhibitor, a flame retardant, an inorganic filler, a surfactant, a coloring agent, a toughening agent, a solvent, or a combination thereof.

17. An article made from the resin composition of claim 13, characterized in that the article comprises a prepreg, a resin film, a laminate, or a printed circuit board.

18. The article of claim 17, characterized in that the article has at least one of the following properties:
an X-CTE at board center of less than or equal to 3.8 ppm/° C. as measured and calculated by reference to IPC-TM-650 2.4.24.5;
an X-CTE at board edge of less than or equal to 4.0 ppm/° C. as measured and calculated by reference to IPC-TM-650 2.4.24.5;
a difference between the X-CTE at board center and the X-CTE at board edge of less than or equal to 0.3 ppm/° C. as measured and calculated by reference to IPC-TM-650 2.4.24.5;
a copper foil peeling strength after copper plating of greater than or equal to 5.0 lb/in as measured by reference to IPC-TM-650 2.4.8;
a dimension change Cpk of a substrate after solder floating of greater than or equal to 1.35 as measured and calculated by reference to IPC-TM-650 2.4.39;
a glass transition temperature of greater than or equal to 330° C. as measured by reference to IPC-TM-650 2.4.24.4.
